(19) United States
(12) Patent Application Publication
(10) Pub. No.: US 2024/0306515 A1
(43) Pub. Date: Sep. 12, 2024

(54) MAGNETIC ELEMENT AND MAGNETIC MEMORY

(71) Applicant: TDK CORPORATION, Tokyo (JP)

(72) Inventor: Yugo Ishitani, Tokyo (JP)

(73) Assignee: TDK CORPORATION, Tokyo (JP)

(21) Appl. No.: 18/598,111

(22) Filed: Mar. 7, 2024

(30) Foreign Application Priority Data
Mar. 10, 2023 (WO) PCT/JP2023/009302
Mar. 10, 2023 (WO) PCT/JP2023/009319

(51) Int. Cl. H10N 50/10; H10B 61/00; H10N 50/85

(52) U.S. Cl. CPC H10N 50/10; H10B 61/00; H10N 50/85

(57) ABSTRACT

This magnetic element includes a spin orbit torque wiring, and a laminate including a first ferromagnetic layer. The spin orbit torque wiring includes three or more layers. Combinations of materials of the layers in the spin orbit torque wiring are asymmetric in a lamination direction. A sequence of material types in which the materials of the layers of the spin orbit torque wiring are arranged from a first surface in contact with the laminate toward a second surface on a side opposite to the first surface differs from a sequence of material types in which the materials of the layers of the spin orbit torque wiring are arranged from the second surface toward the first surface.

### BACKGROUND

### Field

The present disclosure relates to a magnetic element and a magnetic memory. Priority is claimed on PCT/JP2023/009302, and PCT/JP2023/009319, filed for WIPO on Mar. 10, 2023, the contents of which are incorporated herein by reference.

### DESCRIPTION OF RELATED ART

Giant magnetoresistive (GMR) elements constituted of a multilayer film with a ferromagnetic layer and a non-magnetic layer, and tunnel magnetoresistive (TMR) elements using an insulating layer (a tunnel barrier layer or a barrier layer) for a non-magnetic layer are known as magnetoresistive effect elements. Magnetoresistive effect elements can be applied to magnetic sensors, high-frequency components, magnetic heads and non-volatile random access memories (MRAMs).

MRAMs are memory elements in which magnetoresistive effect elements are integrated. An MRAM reads and writes data utilizing the characteristics in which a resistance of a magnetoresistive effect element changes in response to change in directions of magnetizations of two ferromagnetic layers with a non-magnetic layer interposed therebetween in the magnetoresistive effect element. For example, the direction of the magnetization of the ferromagnetic layer is controlled utilizing a magnetic field generated by an electric current. In addition, for example, the direction of the magnetization of the ferromagnetic layer is controlled utilizing a spin transfer torque (STT) generated by causing an electric current to flow in a lamination direction of the magnetoresistive effect element.

When the direction of the magnetization of the ferromagnetic layer is rewritten utilizing an STT, an electric current is caused to flow in the lamination direction of the magnetoresistive effect element. A write current will cause deterioration in characteristics of the magnetoresistive effect element.

In recent years, methods which do not require an electric current to flow in a lamination direction of a magnetoresistive effect element during writing have attracted attention. One of such methods is a writing method utilizing a spin orbit torque (SOT) (for example, Patent Document 1). An SOT is generated by a spin current induced due to a spin orbit interaction or a Rashba effect in interfaces of dissimilar materials. An electric current for inducing an SOT into a magnetoresistive effect element flows in a direction intersecting the lamination direction of the magnetoresistive effect element. That is, there is no need for an electric current to flow in the lamination direction of the magnetoresistive effect element, and therefore it is expected that life-spans of magnetoresistive effect elements will be extended.

### Patent Document

[Patent Document 1] Japanese Unexamined Patent Application, First Publication No. 2017-216286

### SUMMARY

In a magnetoresistive effect element using a spin orbit torque (SOT), if an electric current density of a write current flowing in a spin orbit torque wiring becomes equal to or higher than a predetermined value, the magnetization of a ferromagnetic layer is reversed. An electric current density of a write current at which the magnetization of the ferromagnetic layer is reversed is referred to as a reversal current density. In order to enhance the efficiency of writing a signal in a magnetoresistive effect element, it is required to reduce the reversal current density. In order to reduce the reversal current density, it is required to cause a spin orbit torque induced due to a Rashba effect in interfaces to efficiently act on the ferromagnetic layer.

The present disclosure is made in consideration of the foregoing circumstances, and an object thereof is to provide a magnetic element and a magnetic memory capable of causing a spin orbit torque induced due to a Rashba effect in interfaces to efficiently act on a ferromagnetic layer.

In order to resolve the foregoing problems, the present invention provides the following means.

This magnetic element includes a spin orbit torque wiring and a laminate. The laminate comes into contact with the spin orbit torque wiring and includes a first ferromagnetic layer. The spin orbit torque wiring includes three or more layers. Combinations of materials of the layers in the spin orbit torque wiring are asymmetric in a lamination direction. A sequence of material types in which the materials of the layers of the spin orbit torque wiring are arranged from a first surface in contact with the laminate toward a second surface on a side opposite to the first surface differs from a sequence of material types in which the materials of the layers of the spin orbit torque wiring are arranged from the second surface toward the first surface.

The magnetic element and the magnetic memory according to the present disclosure can cause a spin orbit torque induced due to a Rashba effect in interfaces to efficiently act on a ferromagnetic layer.

### BRIEF DESCRIPTION OF THE DRAWINGS

FIG. 1 is a circuit diagram of a magnetic memory according to a first embodiment.

FIG. 2 is a cross-sectional view of a characteristic portion of the magnetic memory according to the first embodiment.

FIG. 3 is a cross-sectional view of a magnetoresistive effect element according to the first embodiment.

FIG. 4 is a plan view of the magnetoresistive effect element according to the first embodiment.

FIG. 5 is an enlarged view of a characteristic portion of a spin orbit torque wiring according to the first embodiment.

FIG. 6 is a cross-sectional view of a magnetoresistive effect element according to a first modification example of the first embodiment.

FIG. 7 is a cross-sectional view of a magnetization rotation element according to a second modification example of the first embodiment.

FIG. 8 is a cross-sectional view of a magnetoresistive effect element according to a second embodiment.

FIG. 9 is a cross-sectional view of a spin orbit torque wiring according to the second embodiment.

FIG. 10 is a view showing a relationship between a degree of asymmetry of the spin orbit torque wiring and a spin Hall angle of the spin orbit torque wiring.

FIG. 11 is an enlarged view of a characteristic portion of the spin orbit torque wiring according to the second embodiment.

FIG. 12 is a cross-sectional view of a magnetoresistive effect element according to a first modification example of the second embodiment.

FIG. 13 is a cross-sectional view of a magnetization rotation element according to a second modification example of the second embodiment.

### DETAILED DESCRIPTION OF THE INVENTION

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

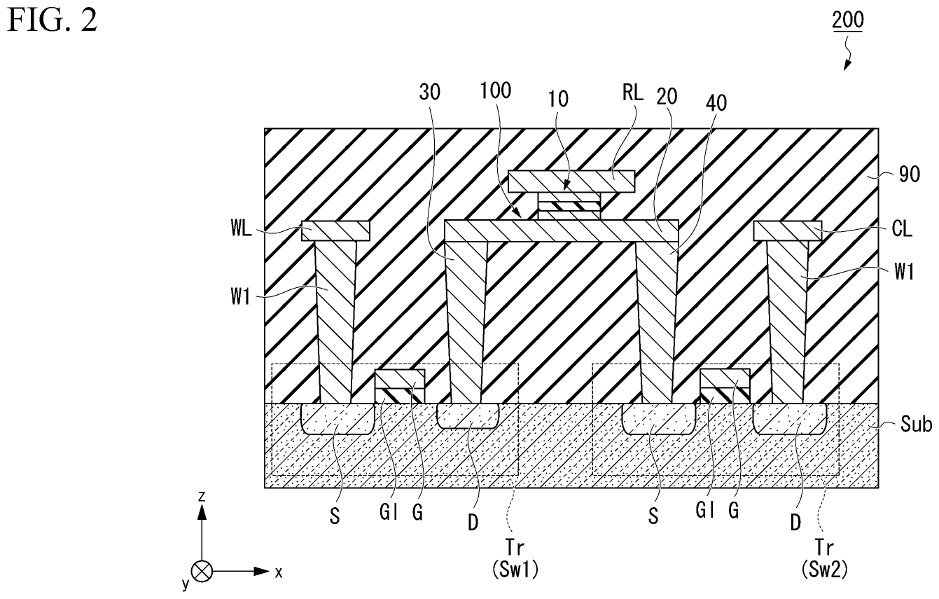

First, directions will be defined. One direction on a surface of a substrate Sub which will be described below (refer to FIG. 2) will be referred to as an x direction, and a direction orthogonal to the x direction will be referred to as a y direction. For example, the x direction is a longitudinal direction of a spin orbit torque wiring 20. A z direction is a direction orthogonal to the x direction and the y direction. The z direction is an example of a lamination direction in which the layers are laminated. Hereinafter, a positive z direction may be expressed as “upward”, and a negative z direction may be expressed as “downward”. The upward and downward directions do not necessarily match the direction in which the force of gravity is applied.

In this specification, for example, “extending in the x direction” denotes that the dimension in the x direction is larger than the smallest dimension of the dimensions in the x direction, the y direction, and the z direction. The same applies to cases of extending in other directions. In addition, in this specification, “connection” is not limited to the case of being physically connected. For example, “connection” is not limited to the case where two layers physically come into contact with each other, and it also includes a case where two layers are connected to each other with a different layer interposed therebetween. In addition, in this specification, “connection” also includes electrical connection. In addition, in this specification, “facing” denotes a relationship between two layers facing each other, and the two layers may be in contact with each other and may face each other with a different layer interposed therebetween.

### First Embodiment

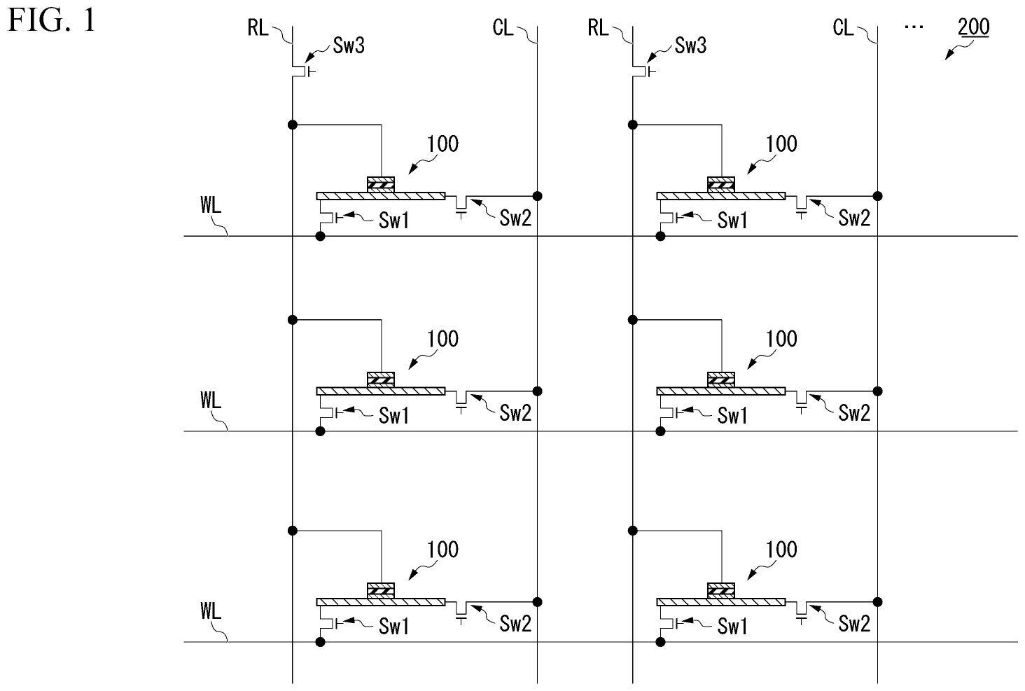

FIG. 1 is a view of a constitution of a magnetic memory 200 according to a first embodiment. The magnetic memory 200 includes a plurality of magnetoresistive effect elements 100, a plurality of write wirings WL, a plurality of common wirings CL, a plurality of read wirings RL, a plurality of first switching elements Sw1, a plurality of second switching elements Sw2, and a plurality of third switching elements Sw3. For example, in the magnetic memory 200, the magnetoresistive effect elements 100 are arrayed in a matrix shape. The magnetoresistive effect element 100 is an example of a magnetic element.

Each of the write wirings WL electrically connects a power source to one or more magnetoresistive effect elements 100. Each of the common wirings CL is a wiring used during both writing and reading of data. Each of the common wirings CL electrically connects a reference potential to one or more magnetoresistive effect elements 100. For example, the reference potential is a ground potential. The common wiring CL may be provided in each of the plurality of magnetoresistive effect elements 100 or may be provided across the plurality of magnetoresistive effect elements 100. Each of the read wirings RL electrically connects the power source to one or more magnetoresistive effect elements 100. The power source is connected to the magnetic memory 200 when in use.

Each of the magnetoresistive effect elements 100 is electrically connected to each of the first switching element Sw1, the second switching element Sw2, and the third switching element Sw3. The first switching element Sw1 is connected between the magnetoresistive effect element 100 and the write wiring WL. The second switching element Sw2 is connected between the magnetoresistive effect element 100 and the common wiring CL. The third switching element Sw3 is connected to the read wiring RL across the plurality of magnetoresistive effect elements 100.

If a predetermined first switching element Sw1 and a predetermined second switching element Sw2 are turned on, a write current flows between the write wiring WL and the common wiring CL connected to a predetermined magnetoresistive effect element 100. Data is written in the predetermined magnetoresistive effect element 100 in response to a flow of a write current. If a predetermined second switching element Sw2 and a predetermined third switching element Sw3 are turned on, a read current flows between the common wiring CL and the read wiring RL connected to a predetermined magnetoresistive effect element 100. Data is read from the predetermined magnetoresistive effect element 100 in response to a flow of a read current.

The first switching elements Sw1, the second switching elements Sw2, and the third switching elements Sw3 are elements controlling flows of an electric current. For example, the first switching elements Sw1, the second switching elements Sw2, and the third switching elements Sw3 are elements such as transistors, ovonic threshold switches (OTSs) utilizing phase change in crystal layer, elements such as metal-insulator transition (MIT) switches utilizing change in band structure, elements such as Zener diodes and avalanche diodes utilizing a breakdown voltage, or elements whose conductivity changes in response to change in atom position.

In the magnetic memory 200 shown in FIG. 1, the third switching element Sw3 is shared by the magnetoresistive effect elements 100 connected to the same read wiring RL. The third switching element Sw3 may be provided in each of the magnetoresistive effect elements 100. In addition, the third switching element Sw3 may be provided in each of the magnetoresistive effect elements 100, and the first switching element Sw1 or the second switching element Sw2 may be shared by the magnetoresistive effect elements 100 connected to the same wiring.

FIG. 2 is a cross-sectional view of a characteristic portion of the magnetic memory 200 according to the first embodiment. FIG. 2 is a cross section of the magnetoresistive effect element 100 cut along an xz plane passing through the center of the width of the spin orbit torque wiring 20 (which will be described below) in the y direction.

The first switching element Sw1 and the second switching element Sw2 shown in FIG. 2 are transistors Tr. The third switching element Sw3 is electrically connected to the read wiring RL and is located, for example, at a different position in the y direction in FIG. 2. For example, the transistor Tr is a field effect-type transistor having a gate electrode G, a gate insulating film GI, and a source S and a drain D formed on the substrate Sub. The source S and the drain D are prearranged in accordance with a flow direction of an electric current, and these are in the same region. The positional relationship of the source S and the drain D may be reversed. For example, the substrate Sub is a semiconductor substrate.

The transistors Tr and the magnetoresistive effect element 100 are electrically connected via a first via wiring 30 and a second via wiring 40. In addition, each of the transistors Tr is connected to the write wiring WL or the common wiring CL via a via wiring W1. Each of the first via wiring 30, the second via wiring 40, and the via wiring W1 extends in the z direction, for example. Each of the first via wiring 30, the second via wiring 40, and the via wiring W1 may be a wiring in which a plurality of columnar bodies are laminated. Each of the first via wiring 30, the second via wiring 40, and the via wiring W1 includes a conductive material.

An area around the magnetoresistive effect element 100 and the transistors Tr is covered by an insulating layer 90. The insulating layer 90 is an insulating layer for insulating wirings in a multilayer wiring or elements from each other. For example, the insulating layer 90 is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), magnesium oxide (MgO), aluminum nitride (AlN), or the like.

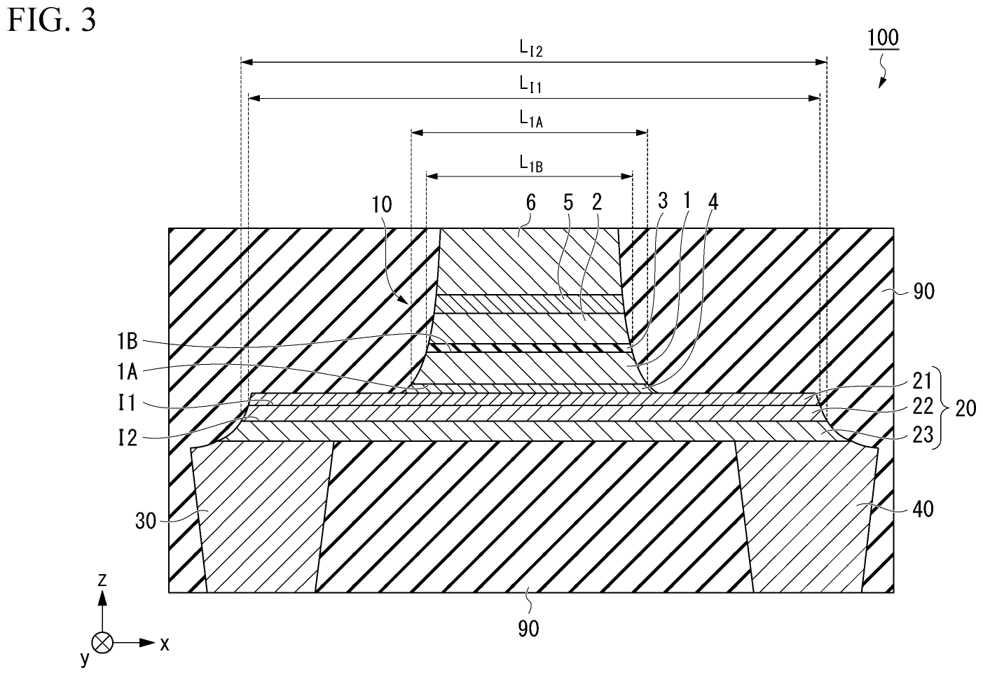

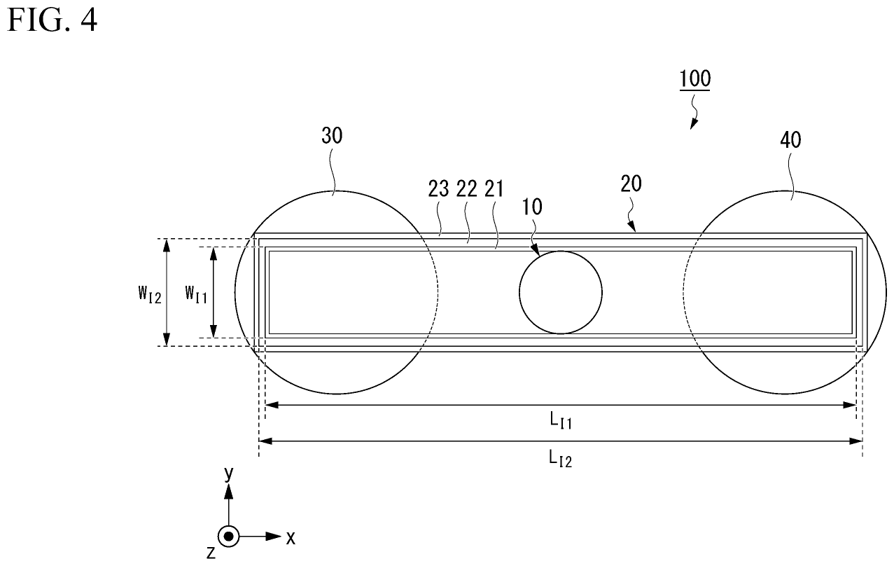

FIG. 3 is a cross-sectional view of the magnetoresistive effect element 100. FIG. 3 is a cross section of the magnetoresistive effect element 100 cut along an xz plane passing through the center of the width of the spin orbit torque wiring 20 in the y direction. FIG. 4 is a plan view of the magnetoresistive effect element 100 viewed in the z direction.

For example, the magnetoresistive effect element 100 includes a laminate 10 and the spin orbit torque wiring 20.

The magnetoresistive effect element 100 is a magnetic element utilizing a spin orbit torque (SOT) and may be referred to as a spin orbit torque-type magnetoresistive effect element, a spin injection-type magnetoresistive effect element, or a spin current magnetoresistive effect element.

The magnetoresistive effect element 100 is an element for recording and saving data. The magnetoresistive effect element 100 records data based on a resistance value of the laminate 10 in the z direction. The resistance value of the laminate 10 in the z direction changes when a write current is applied along the spin orbit torque wiring 20 and spins are injected from the spin orbit torque wiring 20 to the laminate 10. The resistance value of the laminate 10 in the z direction can be read by applying a read current in the z direction of the laminate 10.

The laminate 10 is connected to the spin orbit torque wiring 20. For example, the laminate 10 shown in FIG. 3 is laminated on the spin orbit torque wiring 20.

The laminate 10 is a columnar body. For example, the shape of the laminate 10 in the z direction in a plan view is a circular shape, an oval shape, or a quadrangular shape. For example, the side surfaces of the laminate 10 are inclined with respect to the z direction.

For example, the laminate 10 includes a first ferromagnetic layer 1, a second ferromagnetic layer 2, a non-magnetic layer 3, a base layer 4, a cap layer 5, and a mask layer 6. In the laminate 10, the resistance value changes in accordance with a difference in a relative angle between magnetizations of the first ferromagnetic layer 1 and the second ferromagnetic layer 2 with the non-magnetic layer 3 interposed therebetween.

For example, the first ferromagnetic layer 1 faces the spin orbit torque wiring 20. The first ferromagnetic layer 1 may directly come into contact with the spin orbit torque wiring 20 or may indirectly come into contact with it via the base layer 4. For example, the first ferromagnetic layer 1 is laminated on the spin orbit torque wiring 20.

Side surfaces of the first ferromagnetic layer 1 are inclined. A length L_{1A} of a first surface 1A of the first ferromagnetic layer 1 on the spin orbit torque wiring 20 side in the x direction is longer than a length L_{1B} of a second surface 1B on a side opposite to the first surface 1A in the x direction. The first surface 1A in FIG. 3 is closer to the substrate Sub than the second surface 1B.

Spins are injected into the first ferromagnetic layer 1 from the spin orbit torque wiring 20. The magnetization of the first ferromagnetic layer 1 receives a spin orbit torque (SOT) due to injected spins, and the orientation direction thereof changes. The first ferromagnetic layer 1 is referred to as a magnetization free layer.

The first ferromagnetic layer 1 includes a ferromagnetic body. For example, the ferromagnetic body is a metal selected from the group consisting of Cr, Mn, Co, Fe, and Ni; an alloy including one or more kinds of these metals; an alloy including at least one or more kinds of elements of these metals, B, C, and N; or the like. For example, a ferromagnetic body is Co—Fe, Co—Fe—B, Ni—Fe, a Co—Ho alloy, a Sm—Fe alloy, a Fe—Pt alloy, a Co—Pt alloy, or a CoCrPt alloy.

The first ferromagnetic layer 1 may include a Heusler alloy. The Heusler alloy includes an intermetallic compound having a chemical composition of XYZ or X₂YZ. X is a transition metal element from the Co, Fe, Ni, or Cu groups or a noble metal element on the periodic table. Y is a transition metal from the Mn, V, Cr, or Ti groups or the same kind of element as X. Z is a typical element from Group III to Group V. For example, the Heusler alloy is Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarizability.

The second ferromagnetic layer 2 faces the first ferromagnetic layer 1 with the non-magnetic layer 3 interposed therebetween. The second ferromagnetic layer 2 includes a ferromagnetic body. The orientation direction of the magnetization of the second ferromagnetic layer 2 is less likely to change than that of the magnetization of the first ferromagnetic layer 1 when a predetermined external force is applied. The second ferromagnetic layer 2 is referred to as a magnetization fixed layer or a magnetization reference layer. In the laminate 10 shown in FIG. 3, the magnetization fixed layer is located on a side away from the substrate Sub and is referred to as a top pin structure.

A material similar to that constituting the first ferromagnetic layer 1 is used as a material constituting the second ferromagnetic layer 2.

The second ferromagnetic layer 2 may have a synthetic antiferromagnetic structure (SAF structure). The synthetic antiferromagnetic structure is constituted of two magnetic layers with a non-magnetic layer interposed therebetween. The second ferromagnetic layer 2 may have two magnetic layers and interposed therebetween a spacer layer. Antiferromagnetic coupling between two ferromagnetic layers makes a coercive force of the second ferromagnetic layer 2 larger. For example, the ferromagnetic layer is made of IrMn, PtMn, or the like. For example, the spacer layer includes at least one selected from the group consisting of Ru, Ir, and Rh.

The non-magnetic layer 3 is interposed between the first ferromagnetic layer 1 and the second ferromagnetic layer 2. The non-magnetic layer 3 includes a non-magnetic body. When the non-magnetic layer 3 is an insulator (in a case of a tunnel barrier layer), for example, Al₂O₃, SiO₂, MgO, MgAl₂O₄, or the like can be used as a material thereof. In addition to these, a material or the like in which a part of Al, Si, and Mg is replaced with Zn, Be, or the like can also be used. Among these, since MgO and MgAl₂O₄ are materials capable of realizing a coherent tunnel, spins can be efficiently injected. When the non-magnetic layer 3 is made of a metal, Cu, Au, Ag, or the like can be used as a material thereof. Moreover, when the non-magnetic layer 3 is a semiconductor, Si, Ge, CuInSe₂, CuGaSe₂, Cu(In,Ga)Se₂, or the like can be used as a material thereof.

For example, the base layer 4 is located between the first ferromagnetic layer 1 and the spin orbit torque wiring 20. The base layer 4 may be omitted.

For example, the base layer 4 includes a buffer layer and a seed layer. The buffer layer is a layer alleviating lattice mismatch between different crystals. The seed layer enhances crystallinity of a layer laminated on the seed layer. For example, the seed layer is formed on the buffer layer.

For example, the buffer layer is made of Ta (single substance), TaN (tantalum nitride), CuN (copper nitride), TiN (titanium nitride), or NiAl (nickel aluminum). For example, the seed layer is made of Pt, Ru, Zr, a NiCr alloy, or NiFeCr.

The cap layer 5 is located on the second ferromagnetic layer 2. For example, the cap layer 5 strengthens the magnetic anisotropy of the second ferromagnetic layer 2. For example, the cap layer 5 strengthens the perpendicular magnetic anisotropy of the second ferromagnetic layer 2. For example, the cap layer 5 is made of magnesium oxide, W, Ta, Mo, or the like. For example, the film thickness of the cap layer 5 is 0.5 nm to 5.0 nm.

The mask layer 6 is located on the cap layer 5. The mask layer 6 is a part of a hard mask used when the laminate 10 is processed during manufacturing. The mask layer 6 also functions as an electrode. For example, the mask layer 6 includes Al, Cu, Ta, Ti, Zr, NiCr, nitrides (for example, TiN, TaN, or SiN), and oxides (for example, SiO₂).

The laminate 10 may also have a layer other than the first ferromagnetic layer 1, the second ferromagnetic layer 2, the non-magnetic layer 3, the base layer 4, the cap layer 5, and the mask layer 6.

For example, the spin orbit torque wiring 20 has a longer length in the x direction than in the y direction when viewed in the z direction and extends in the x direction. A write current flows in the x direction along the spin orbit torque wiring 20 between the first via wiring 30 and the second via wiring 40.

The spin orbit torque wiring 20 induces a spin current due to a spin orbit interaction and an interfacial Rashba effect and injects spins into the first ferromagnetic layer 1. For example, the spin orbit torque wiring 20 applies enough spin orbit torque (SOT) to the magnetization of the first ferromagnetic layer 1 to reverse the magnetization of the first ferromagnetic layer 1.

A spin Hall effect is a phenomenon in which a spin current is induced in a direction orthogonal to the direction in which an electric current flows based on the spin orbit interaction when an electric current flows. The spin Hall effect is in common with an ordinary Hall effect in that a motion (movement) direction is bent due to motion (movement) of electric charge (electrons). In an ordinary Hall effect, the motion direction of charged particles in motion in a magnetic field is bent due to a Lorentz force. In contrast, in the spin Hall effect, the movement direction of spins is bent simply by movement of electrons (simply by a flow of an electric current) even if no magnetic field is present.

For example, if an electric current flows in the spin orbit torque wiring 20, first spins polarized in one direction and second spins polarized in a direction opposite to the first spins are bent due to the spin Hall effect in a direction orthogonal to the direction in which an electric current flows. For example, the first spins polarized in the negative y direction are bent in the positive z direction from the x direction that is a traveling direction thereof, and the second spins polarized in the positive y direction are bent in the negative z direction from the x direction that is a traveling direction thereof.

In a non-magnetic body (a material which is not a ferromagnetic body), the number of electrons in the first spins and the number of electrons in the second spins generated due to the spin Hall effect are equivalent to each other. That is, the number of electrons in the first spins directed in the positive z direction and the number of electrons in the second spins directed in the negative z direction are equivalent to each other. The first spins and the second spins flow in a direction in which uneven distribution of spins is resolved. Since flows of electric charge cancel each other out during movement of the first spins and the second spins in the z direction, the amount of electric current becomes zero. A spin current entailing no electric current is particularly referred to as a pure spin current.

When a flow of electrons in the first spins is expressed as J_{⬆}, a flow of electrons in the second spins is expressed as J_{⬇}, and a spin current is expressed as J_{S}, the spin current is defined as J_{S}=J_{⬆}-J_{⬇}. The spin current J_{S} is generated in the z direction. The first spins are injected into the first ferromagnetic layer 1 from the spin orbit torque wiring 20.

Although the detailed mechanism is not clear, it is said that an interfacial Rashba effect occurs due to breaking of spatial reversal symmetry in an interface between dissimilar materials. In an interface between dissimilar materials, spatial reversal symmetry is broken, and a potential gradient is present in a direction perpendicular to the surface. When an electric current flows along an interface with a potential gradient in such a direction perpendicular to the surface, namely, when electrons are in motion within a two-dimensional plane, an effective magnetic field applies to spins in a direction perpendicular to the motion direction of electrons and an in-plane direction. When directions of spins are aligned in the direction of this effective magnetic field, spin accumulation is occurred in an interface. Further, this spin accumulation diffuses out of the plane, thereby causing spin injection into the first ferromagnetic layer 1 from the spin orbit torque wiring 20.

In order to efficiently inject spins into the first ferromagnetic layer 1 from the spin orbit torque wiring 20, it is required to appropriately utilize the spin orbit interaction and the interfacial Rashba effect.

The spin orbit torque wiring 20 has a first layer 21, a second layer 22, and a third layer 23. Shown in FIG. 3 the spin orbit torque wiring 20 has the third layer 23, the second layer 22, and the first layer 21 in this order from the side closer to the substrate Sub. The first layer 21 comes into contact with the laminate 10. The second layer 22 is interposed between the first layer 21 and the third layer 23 in the z direction. An interface I1 is located in a boundary between the first layer 21 and the second layer 22, and an interface I2 is located in a boundary between the second layer 22 and the third layer 23. The interface I1 is an example of a first interface, and the interface I2 is an example of a second interface.

Each of the first layer 21, the second layer 22, and the third layer 23 includes any of a metal, an alloy, an intermetallic compound, a metal boride, a metal carbide, a metal silicide, a metal phosphide, and a metal nitride having a function of generating a spin current.

For example, each of the first layer 21, the second layer 22, and the third layer 23 includes any one selected from the group consisting of a heavy metal having an atomic number of 39 or larger, a metal oxide, a metal nitride, a metal oxynitride, and a topological insulator.

For example, each of the first layer 21, the second layer 22, and the third layer 23 includes a non-magnetic heavy metal as a main component. A heavy metal denotes a metal having a specific gravity equal to or greater than that of yttrium (Y). For example, a non-magnetic heavy metal is a non-magnetic metal having a large atomic number, such as an atomic number of 39 or larger, and has d electrons or f electrons in an outermost shell. In a non-magnetic heavy metal, a stronger spin orbit interaction occurs than in other metals. The spin Hall effect occurs due to the spin orbit interaction so that spins are likely to be unevenly distributed within the spin orbit torque wiring 20 and the spin current J_{S} is likely to be generated.

Each of the first layer 21, the second layer 22, and the third layer 23 may include a magnetic material. However, in order to prevent the first ferromagnetic layer 1 and the first layer 21 from being magnetically coupled, it is preferable that the first layer 21 be a non-magnetic layer. In addition, each of the first layer 21, the second layer 22, and the third layer 23 may be a topological insulator.

In addition, it is preferable that at least one of the first layer 21, the second layer 22, and the third layer 23 have an impurity concentration of 3 atm % or lower. In addition, it is preferable that all the first layer 21, the second layer 22, and the third layer 23 have an impurity concentration of 3 atm % or lower. If these layers include fewer impurities, a probability of occurrence of transposition inside the spin orbit torque wiring decreases so that the interface between the layers becomes flat. If flatness of the interface is high, the interfacial Rashba effect occurs effectively.

The constituent materials of the first layer 21, the second layer 22, and the third layer 23 are different from each other. For this reason, in the spin orbit torque wiring 20, combinations of the materials of the layers are asymmetric in the lamination direction. A sequence of material types in which the materials of the layers of the spin orbit torque wiring 20 are arranged from a first surface toward a second surface differs from a sequence of material types in which the materials of the layers of the spin orbit torque wiring 20 are arranged from the second surface toward the first surface. The first surface is a surface of the spin orbit torque wiring 20 in contact with the laminate 10. The second surface is a surface on a side opposite to the first surface.

If the constituent materials differ from each other, it is possible to curb a situation in which a spin current generated due to the interfacial Rashba effect in the interface I1 and a spin current generated due to the interfacial Rashba effect in the interface I2 cancel each other out. For example, when the first layer 21 and the third layer 23 having the second layer 22 interposed therebetween are made of the same material, a spin current generated due to the interfacial Rashba effect in the interface I1 and a spin current generated due to the interfacial Rashba effect in the interface I2 cancel each other out.

It is preferable that a combination of elements respectively included in the first layer 21, the second layer 22, and the third layer 23 conform with being any one of the following. The combination of elements respectively included in the first layer 21, the second layer 22, and the third layer 23 will be expressed as (the first layer 21, the second layer 22, and the third layer 23). Examples of (the first layer 21, the second layer 22, and the third layer 23) include (W, Cr, and Mo), (W, Mg, and Mo), (W, V, and Mo), (Ta, Cr, and Mo), (Ta, Mg, and Mo), (Ta, V, and Mo), (Pt, Al, and Ti), (Pt, Cu, and Ti), (Pt, Ru, and Ti), (Pt, Au, and Ti), (Pt, Hf, and Ti), (W, V, and Ta), (W, Mo, and Ta), (W, Mg, and Ta), (W, Cr, and Ta), (W, Al, and Ta), (W, Ti, and Ta), (W, Cu, and Ta), (W, Ru, and Ta), (W, Au, and Ta), (W, Hf, and Ta), (Mg, V, and Mo), (Mg, Cr, and Mo), (Cr, Mg, and Mo), (Ru, Al, and Ti), (Ru, Cu, and Ti), (Ru, Au, and Ti), (Ru, Hf, and Ti), (Hf, Al, and Ti), (Hf, Cu, and Ti), (Hf, Ru, and Ti), (Hf, Au, and Ti), (W, Fe, and Ta), (W, Fe, and Mo), (W, Fe, and Ti), (W, Co, and Ta), (W, Co, and Mo), (W, Co, and Ti), (W, V, and Fe), (W, Mo, and Fe), (W, Mg, and Fe), (W, Cr, and Fe), (W, Al, and Co), (W, Ti, and Co), (W, Cu, and Co), (W, Ru, and Co), (W, Au, and Co), (W, Hf, and Co), (Mg—Al—O, W, and Mo), (Mg—Al—O, W, and Ti), (Mg—Al—O, Pt, and Mo), (Mg—Al—O, Pt, and Ti), (W, Mo, and Ti—N), (W, Mo, and Ta—N), (W, Mo, and Cu—O), (W, Mo, and Cu—N), (W, Mo, and Hf—O), (Pt, Ti, and Ti—N), (Pt, Ti, and Ta—N), (Pt, Ti, and Cu—O), (Pt, Ti, and Cu—N), and (Pt, Ti, and Hf—O). Here, “—” indicates a combination of materials regardless of the composition ratio. For example, Mg—Al—O is an oxide including Mg and Al, and the individual composition ratio thereof is not restricted.

It is more preferable that the combination of elements respectively included in the first layer 21, the second layer 22, and the third layer 23 conform with being any one of the following. Examples of (the first layer 21, the second layer 22, and the third layer 23) preferably include (W, Cr, and Mo), (W, Mg, and Mo), (Pt, Cu, and Ti), (W, Mo, and Ta), (W, Mg, and Ta), (W, Cr, and Ta), (W, Cu, and Ta), (Mg, Cr, and Mo), (Cr, Mg, and Mo), (W, Fe, and Ta), (W, Fe, and Mo), (W, Mo, and Fe), (Mg—Al—O, W, and Mo), (Mg—Al—O, Pt, and Ti), (W, Mo, and Ta—N), and (Pt, Ti, and Ta—N). In addition, it is preferable that the first layer of the spin orbit torque wiring 20 in contact with the laminate 10 be a non-magnetic layer.

It is preferable that the interface I1 and the interface I2 be closer to the first ferromagnetic layer 1 than the center of the spin orbit torque wiring 20 in the z direction. If the interface I1 and the interface I2 are closer to the first ferromagnetic layer 1, it is possible to reduce a loss of spins generated in these interfaces I1 and I2 until they reach the first ferromagnetic layer 1.

The interface I1 and the interface I2 have different areas. For example, a length L_{I1} of the interface I1 in the x direction is shorter than a length L_{I2} of the interface I2 in the x direction. For example, a width W_{I1} of the interface I1 in the y direction is shorter than a width W_{I2} of the interface I2 in the y direction. In FIG. 4, an example in which the interface I1 and the interface I2 differ from each other in length in the x direction and the length in the y direction has been described, but they may differ in only the length in the x direction or in only the length in the y direction. If the interface I1 and the interface I2 have different sizes, it is possible to curb a situation in which a spin current generated due to the interfacial Rashba effect in the interface I1 and a spin current generated due to the interfacial Rashba effect in the interface I2 cancel each other out.

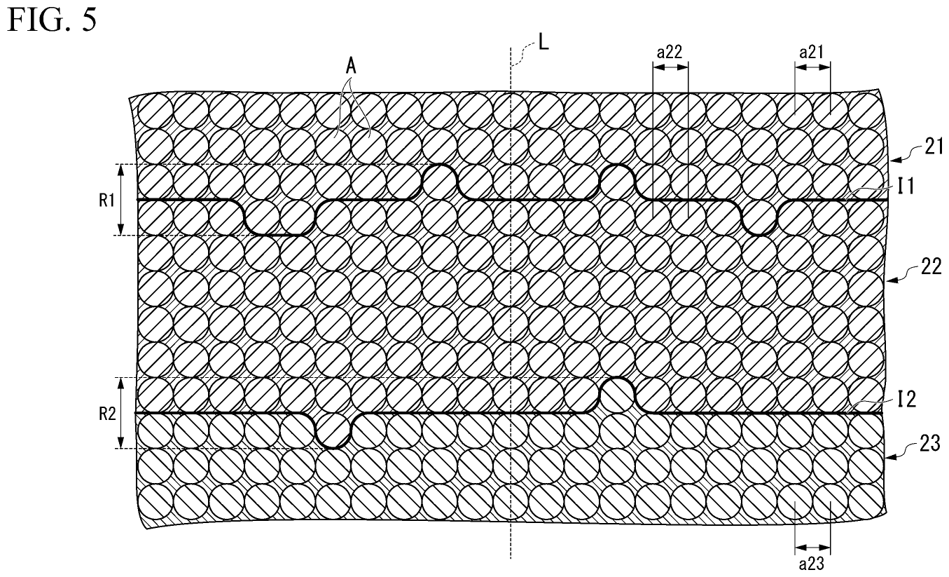

FIG. 5 is an enlarged view of a characteristic portion of a spin orbit torque wiring according to the first embodiment. FIG. 5 schematically shows an arrangement of atoms A in the first layer 21, the second layer 22, and the third layer 23.

It is preferable that at least one of the interface I1 and the interface I2 have 90% or more of a portion in which an interface roughness is two atomic layers or smaller. It is more preferable that the interface I1 have 90% or more of a portion in which an interface roughness R1 is two atomic layers or smaller. In addition, it is particularly preferable that both the interface I1 and the interface I2 have 90% or more of a portion in which the interface roughness R1 and an interface roughness R2 are two atomic layers or smaller.

Here, definitions of the interface roughness R1 and the interface roughness R2 in the present embodiment will be described. When the interface roughness R1 and the interface roughness R2 are evaluated, an interface at a position overlapping the first ferromagnetic layer 1 when viewed in the z direction is measured using a transmission electron microscope, and the array of the atoms A is confirmed. This is because the interface I1 and the interface I2 at positions overlapping the first ferromagnetic layer 1 when viewed in the z direction have a strong influence on spin injection into the first ferromagnetic layer 1.

More specifically, the interface I1 and the interface I2 at positions overlapping the first ferromagnetic layer 1 when viewed in the z direction are evaluated along a width of 10 nm in the x direction. For example, when the width of the first surface 1A of the first ferromagnetic layer 1 in the x direction is 50 nm, the interfaces I1 and I2 are divided into five parts each having a width of 10 nm, and they are individually measured. For example, when the width of the first surface 1A of the first ferromagnetic layer 1 in the x direction is 45 nm, the interfaces I1 and I2 are divided into four parts each having a width of 10 nm at equal intervals, and they are individually measured.

The interface roughness R1 is obtained as a displacement amount of the atoms A in the interface I1. The interface roughness R2 is obtained as a displacement amount of the atoms A in the interface I2. A portion in which the interface roughness in the interface is two atomic layers or smaller is a portion in which deviation of atoms is within a range of two atoms. For example, as described above, when five parts each having a width of 10 nm are measured, the average value of results of the five parts is obtained. If a portion in which the interface roughness R1 and the interface roughness R2 are two atomic layers or smaller is 90% or more, it can be said that the interfaces I1 and I2 are basically flat excluding local spikes, defects, or the like.

For example, the interface roughness R2 of the interface I2 is smaller than the interface roughness R1 of the interface I1. That is, the interface I2 is flatter than the interface I1. The interface I2 is farther from the first ferromagnetic layer 1 than the interface I1. If the interface I2 is flat and there is a large amount of spin current generated due to the interfacial Rashba effect in the interface I2, spins from the interface I2 can be sufficiently delivered to the first ferromagnetic layer 1.

The first layer 21, the second layer 22, and the third layer 23 are epitaxially grown. Here, an example in which these three layers are epitaxially grown has been described, but the first layer 21 and the second layer 22 may be epitaxially grown, or the second layer 22 and the third layer 23 may be epitaxially grown.

Whether or not these layers are epitaxially grown can be confirmed by the fact that the atoms A are consecutively arrayed in an image of a transmission electron microscope (TEM). When the first layer 21, the second layer 22, and the third layer 23 are epitaxially grown, as shown in FIG. 5, if an array of the atoms A is confirmed in order from the lower layer, it is possible to draw a line L in which atoms are arranged in a row. When these layers are not epitaxially grown, obvious distortion can be confirmed and the line L is disconnected on the way from the third layer 23 to the first layer 21.

For example, the lattice misfit rate in the first layer 21 and the second layer 22 is lower than 5%. This lattice misfit rate in the interface is obtained by (“Lattice constant a21 of first layer 21”−“Lattice constant a22 of second layer 22”)/“Lattice constant a22 of second layer 22”.

In addition, for example, the lattice misfit rate in the second layer 22 and the third layer 23 is lower than 5%. This lattice misfit rate in the interface is obtained by (“Lattice constant a22 of second layer 22”−“Lattice constant a23 of third layer 23”)/“Lattice constant a23 of third layer 23”.

If the lattice misfit rate in each interface is within the foregoing range, crystallinity of each layer increases so that the flat interfaces I1 and I2 can be obtained.

Next, a method for manufacturing the magnetoresistive effect element 100 will be described. The magnetoresistive effect element 100 is formed by a laminating step for each layer and a processing step of processing a part of each layer into a predetermined shape. Each layer can be laminated using a sputtering method, a chemical vapor deposition (CVD) method, an electron beam evaporation method (EB evaporation method), an atom laser deposition method, or the like. Each layer can be processed using photolithography or the like.

First, a part of the insulating layer 90 is formed, and an opening is formed at a predetermined position. Next, the inside of the opening is filled with a conductor, and the first via wiring 30 and the second via wiring 40 are formed.

Next, surfaces of the first via wiring 30, the second via wiring 40, and the insulating layer 90 are subjected to chemical mechanical polishing (CMP). Next, a layer which will serve as the third layer 23, a layer which will serve as the second layer 22, and a layer which will serve as the first layer 21 are formed on these surfaces in this order. Every time each of these layers is laminated, the surface thereof is subjected to chemical mechanical polishing. In addition, every time each of these layers is laminated, the surface thereof is subjected to plasma treatment. By performing the foregoing treatment, the interface roughness of the interface I1 between the first layer 21 and the second layer 22 and the interface I2 between the second layer 22 and the third layer 23 can be set within a predetermined range.

Next, the layer which will serve as the third layer 23, the layer which will serve as the second layer 22, and the layer which will serve as the first layer 21 are processed into predetermined shapes, and the spin orbit torque wiring 20 is obtained. Next, an area around the spin orbit torque wiring 20 is covered the insulating layer. Further, a part of the covered insulating layer is subjected to chemical mechanical polishing. By performing chemical mechanical polishing, an upper surface of the spin orbit torque wiring 20 is exposed and flattened.

Next, on the spin orbit torque wiring 20, a base layer, a ferromagnetic layer, a non-magnetic layer, a ferromagnetic layer, and a cap layer are laminated in this order. Further, the mask layer 6 is formed in a portion of a part of the cap layer. Next, the laminate 10 is obtained by processing each of the laminated layers into a predetermined shape via the mask layer 6. Further, the magnetoresistive effect element 100 is obtained by covering the area around the laminate 10 with an insulating layer.

In the magnetoresistive effect element 100 according to the first embodiment, since the materials of the first layer 21, the second layer 22, and the third layer 23 are different from each other, it is possible to curb a situation in which spins generated in the interface I1 and spins generated in the interface I2 cancel each other out. In addition, since the interface I1 and the interface I2 have different areas, it is possible to further curb a situation in which spins generated in the interface I1 and spins generated in the interface I2 cancel each other out. In addition, since the interface roughness R1 and the interface roughness R2 of the interface I1 and the interface I2 are within a predetermined range, a spin current due to the interfacial Rashba effect can be more efficiently generated in each of the interface I1 and the interface I2.

### First Modification Example

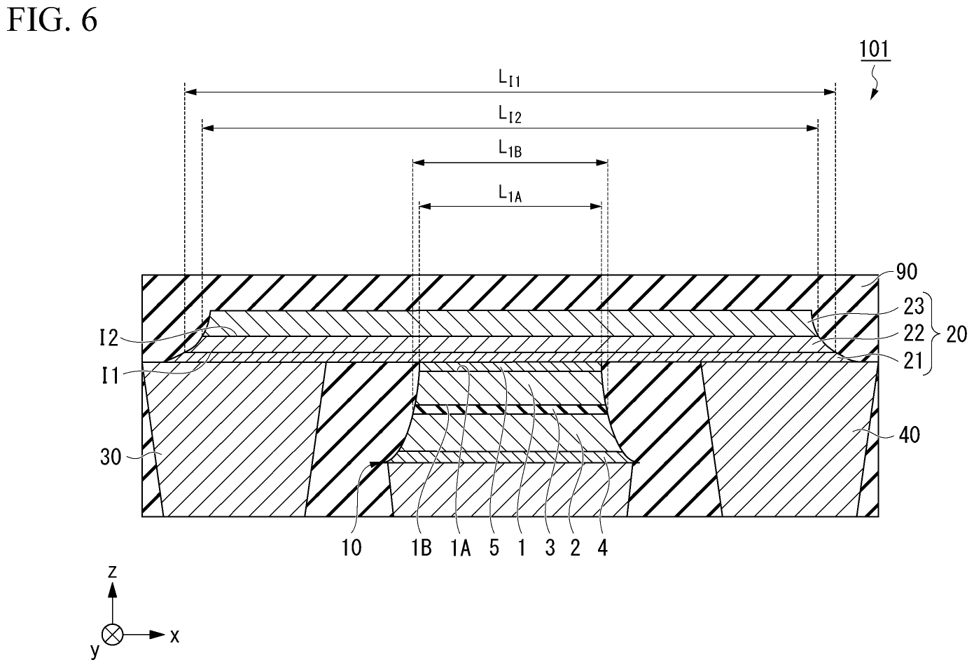

FIG. 6 is a cross-sectional view of a magnetoresistive effect element 101 according to a first modification example of the first embodiment. In the magnetoresistive effect element 101 according to the first modification example of the first embodiment, the same reference signs are applied to constituents similar those of the magnetoresistive effect element 100, and description thereof will be omitted.

The magnetoresistive effect element 101 according to the first modification example of the first embodiment differs from the magnetoresistive effect element 100 in laminating order of the laminate 10 and the spin orbit torque wiring 20. The spin orbit torque wiring 20 is laminated on the laminate 10.

The laminate 10 has the base layer 4, the second ferromagnetic layer 2, the non-magnetic layer 3, the first ferromagnetic layer 1, and the cap layer 5 in this order from the side closer to the substrate Sub. In the magnetoresistive effect element 101, the second ferromagnetic layer 2 (magnetization fixed layer) is closer to the substrate Sub than the first ferromagnetic layer 1 and is referred to as a bottom pin structure. The length L_{1A} of the first surface 1A of the first ferromagnetic layer 1 on the spin orbit torque wiring 20 side in the x direction is shorter than the length L_{1B} of the second surface 1B on a side opposite to the first surface 1A in the x direction.

The spin orbit torque wiring 20 shown in FIG. 6 has the first layer 21, the second layer 22, and the third layer 23 in this order from the side closer to the substrate Sub.

For example, the length L_{I1} of the interface I1 in the x direction is longer than the length L_{I2} of the interface I2 in the x direction. If the interface I1 and the interface I2 have different sizes, it is possible to curb a situation in which a spin current generated due to the interfacial Rashba effect in the interface I1 and a spin current generated due to the interfacial Rashba effect in the interface I2 cancel each other out. In addition, the interface I1 and the interface I2 may have different widths in the y direction. For example, the width Wₙ of the interface I1 in the y direction may be longer than the width W_{I2} of the interface I2 in the y direction.

The interface roughness R1 of the interface I1 is smaller than the interface roughness R2 of the interface I2. That is, the interface I1 is flatter than the interface I2. The interface I1 is closer to the first ferromagnetic layer 1 than the interface I2. For this reason, spins generated due to the interfacial Rashba effect in the interface I1 are less likely to scatter than spins generated due to the interfacial Rashba effect in the interface I2 until they reach the first ferromagnetic layer 1. If the interface I1 is flat, a large amount of spins are generated in the interface I1 so that more spins can be injected into the first ferromagnetic layer 1.

The magnetoresistive effect element 101 according to the first modification example of the first embodiment exhibits effects similar to those of the magnetoresistive effect element 100.

### Second Modification Example

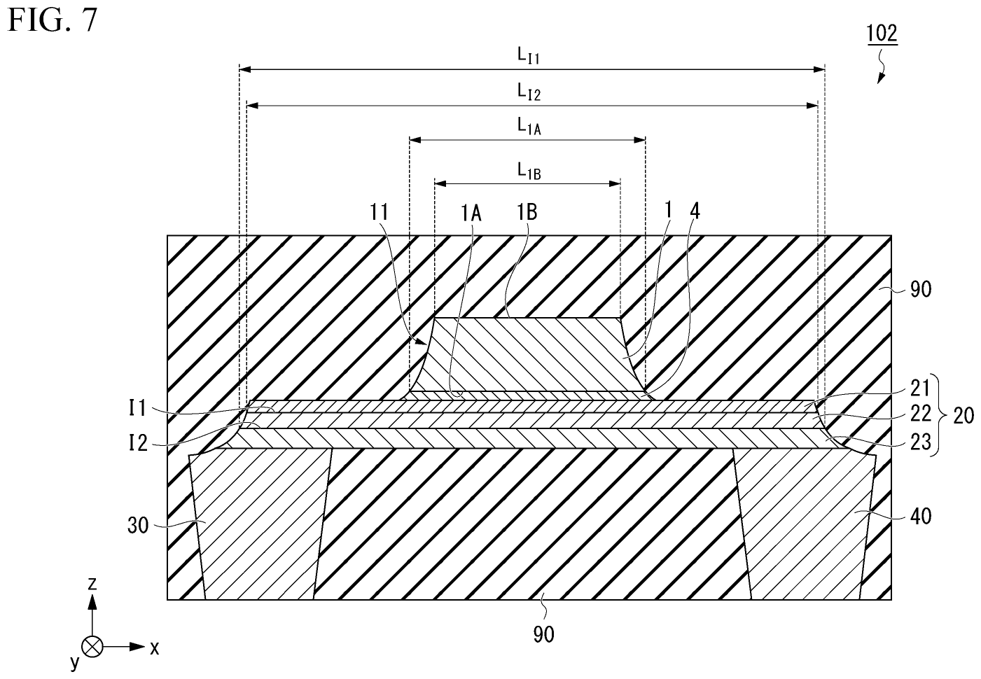

FIG. 7 is a cross-sectional view of a magnetization rotation element 102 according to a second modification example of the first embodiment. The magnetoresistive effect element 100 in FIG. 1 is replaced with the magnetization rotation element 102. The magnetization rotation element 102 differs from the magnetoresistive effect element 100 in that the second ferromagnetic layer 2 and the non-magnetic layer 3 are not provided. The magnetization rotation element 102 is an example of a magnetic element.

For example, in the magnetization rotation element 102, light is incident on the first ferromagnetic layer 1, and light reflected by the first ferromagnetic layer 1 is evaluated. If the orientation direction of the magnetization changes due to a magnetic Kerr effect, the deflection state of reflected light changes. For example, the magnetization rotation element 102 can be used as an optical element such as a video display device, for example, utilizing the difference in light deflection state.

Furthermore, the magnetization rotation element 102 can also be utilized alone as an anisotropic magnetic sensor, an optical element utilizing a magnetic Faraday effect, or the like.

The magnetization rotation element 102 according to the second modification example is obtained by simply removing the non-magnetic layer 3 and the second ferromagnetic layer 2 from the magnetoresistive effect element 100, and it is possible to achieve effects similar to those of the magnetoresistive effect element 100 according to the first embodiment.

### Second Embodiment

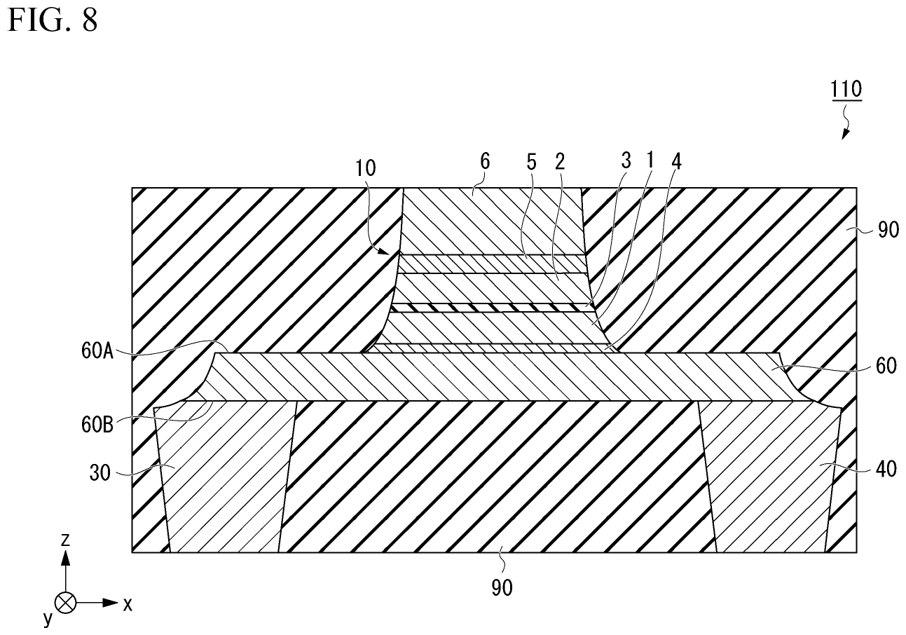

FIG. 8 is a cross-sectional view of a magnetoresistive effect element 110 according to a second embodiment. For example, the magnetoresistive effect element 110 includes the laminate 10 and a spin orbit torque wiring 60. In the magnetoresistive effect element 110, the constitution of the spin orbit torque wiring 60 differs from that of the spin orbit torque wiring 20 according to the first embodiment.

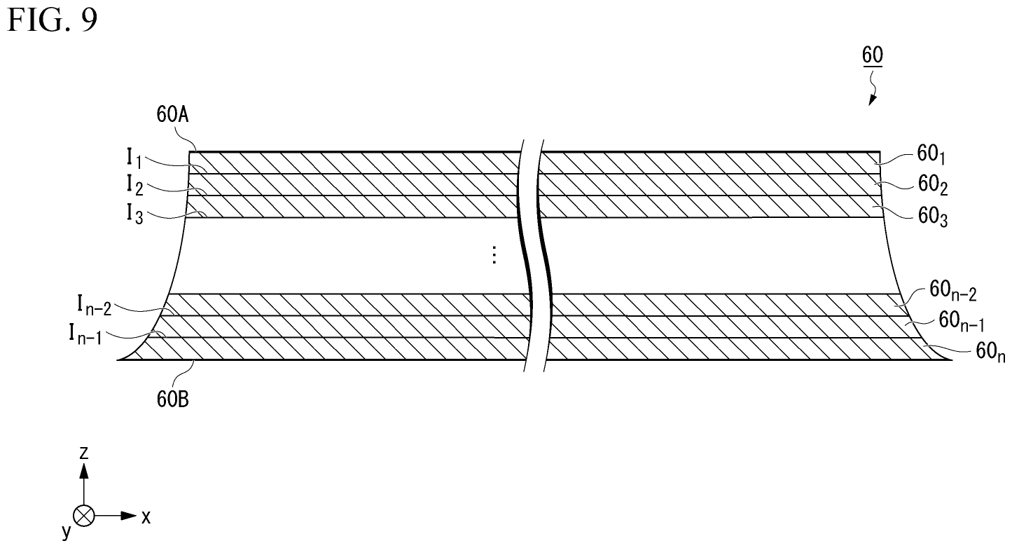

FIG. 9 is a cross-sectional view of the spin orbit torque wiring 60 according to the second embodiment. The spin orbit torque wiring 60 differs from the spin orbit torque wiring 20 according to the first embodiment in having four or more layers. For example, the spin orbit torque wiring 60 may be constituted of four layers or may be constituted of five layers.

For example, the spin orbit torque wiring 60 has a longer length in the x direction than in the y direction when viewed in the z direction and extends in the x direction. For example, the length of a first surface 60A of the spin orbit torque wiring 60 in the x direction is shorter than the length of a second surface 60B of the spin orbit torque wiring 60 in the x direction. The first surface 60A is a surface of the spin orbit torque wiring 60 in contact with the laminate 10. The second surface 60B is a surface of the spin orbit torque wiring 60 on a side opposite to the first surface 60A. A write current flows in the x direction along the spin orbit torque wiring 60 between the first via wiring 30 and the second via wiring 40.

The spin orbit torque wiring 60 shown in FIG. 9 has a first layer 60₁, a second layer 60₂, a third layer 60₃, and so on to n layers (n is an integer of 4 or larger), such as an n−2th layer 60ₙ₋₂, an n−1th layer 60ₙ₋₁, and an nth layer 60ₙ, in this order from the side closer to the first surface 60A. In addition, the spin orbit torque wiring 60 has n−1 interfaces. Hereinafter, they will be referred to as a first interface I₁, a second interface I₂, a third interface I₃, so on to an n−2th interface Iₙ₋₂, and an n−1th interface Iₙ₋₁ in this order from the side closer to the first surface 60A.

The position of an interface is obtained by performing measurement in a thickness direction using energy dispersive X-ray spectroscopy (EDS). For example, if a first material included in the first layer 60₁ is subjected to EDS measurement, an intensity distribution having a peak near the center of the first layer 60₁ in the z direction is obtained. Similarly, if a second material included in the second layer 60₂ is subjected to EDS measurement, an intensity distribution having a peak near the center of the second layer 60₂ in the z direction is obtained. A position where a curve indicating the intensity distribution of the first material and a curve indicating the intensity distribution of the second material intersect corresponds to the first interface I₁.

Each of the layers constituting the spin orbit torque wiring 60 includes any of a metal, an alloy, an intermetallic compound, a metal boride, a metal carbide, a metal silicide, a metal phosphide, and a metal nitride having a function of generating a spin current. Materials which can be used for each of the layers constituting the spin orbit torque wiring 60 are similar to those in the spin orbit torque wiring 20.

For example, when the spin orbit torque wiring 60 has a four-layer structure, it is preferable that a combination of elements respectively included in a first layer, a second layer, a third layer, and a fourth layer conform with being any one of the following. Here, the first layer, the second layer, the third layer, and the fourth layer are closer to the laminate 10 in this order. The combination of elements respectively included in the first layer, the second layer, the third layer, and the fourth layer will be expressed as (the first layer, the second layer, the third layer, and the fourth layer).

Examples of (the first layer, the second layer, the third layer, and the fourth layer) include (W, Cr, Mo, and Ti), (W, Mg, Mo, and Ti), (W, V, Mo, and Ti), (W, Mg, Cr, and Mo), (Ta, Cr, Mo, and Ti), (Ta, Mg, Mo, and Ti), (Ta, V, Mo, and Ti), (Ta, Mg, Cr, and Mo), (Pt, Al, Ti, and Mo), (Pt, Cu, Ti, and Mo), (Pt, Ru, Ti, and Mo), (Pt, Au, Ti, and Mo), (Pt, Hf, Ti, and Mo), (Pt, Hf, Cu, and Ti), (W, V, Ta, and Mo), (W, Mo, Ta, and Ti), (W, Mg, Ta, and Mo), (W, Cr, Ta, and Mo), (W, Al, Ta, and Ti), (W, Ti, Ta, and Mo), (W, Cu, Ta, and Ti), (W, Ru, Ta, and Ti), (W, Au, Ta, and Ti), (W, Hf, Ta, and Ti), (Mg, V, Mo, and Ti), (Mg, Cr, Mo, and Ti), (Cr, Mg, Mo, and Ti), (Ru, Al, Ti, and Mo), (Ru, Cu, Ti, and Mo), (Ru, Au, Ti, and Mo), (Ru, Hf, Ti, and Mo), (Hf, Al, Ti, and Mo), (Hf, Cu, Ti, and Mo), (Hf, Ru, Ti, and Mo), (Hf, Au, Ti, and Mo), (W, Fe, Ta, and Mo), (W, Fe, Mo, and Ti), (W, Fe, Ti, and Mo), (W, Fe, Hf, and Ti), (W, Co, Ta, and Mo), (W, Co, Mo, and Ti), (W, Co, Ti, and Mo), (W, Co, Hf, and Ti), (W, V, Fe, and Mo), (W, Mo, Fe, and Ti), (W, Mg, Fe, and Mo), (W, Cr, Fe, and Mo), (W, Al, Co, and Ti), (W, Ti, Co, and Mo), (W, Cu, Co, and Ti), (W, Ru, Co, and Ti), (W, Au, Co, and Ti), (W, Hf, Co, and Ti), (Mg—Al—O, W, Cr, and Mo), (Mg—Al—O, W, Mg, and Mo), (Mg—Al—O, W, V, and Mo), (Mg—Al—O, Pt, Al, and Ti), (Mg—Al—O, Pt, Cu, and Ti), (Mg—Al—O, Pt, Ru, and Ti), (Mg—Al—O, Pt, Au, and Ti), (Mg—Al—O, Pt, Hf, and Ti), (W, Mg, Mo, and Ti—N), (W, Mg, Mo, and Ta—N), (W, Mg, Mo, and Cu—O), (W, Mg, Mo, and Cu—N), (W, Mg, Mo, and Hf—O), (Pt, Hf, Ti, and Ti—N), (Pt, Hf, Ti, and Ta—N), (Pt, Hf, Ti, and Cu—O), (Pt, Hf, Ti, and Cu—N), and (Pt, Hf, Ti, and Hf—O).

It is more preferable that the combination of elements respectively included in the first layer, the second layer, the third layer, and the fourth layer conform with being any one of the following. Examples of (the first layer, the second layer, the third layer, and the fourth layer) preferably include (W, Cr, Mo, and Ti), (W, Mg, Mo, and Ti), (W, Mg, Cr, and Mo), (Pt, Cu, Ti, and Mo), (W, Mo, Ta, and Ti), (W, Mg, Ta, and Mo), (W, Cr, Ta, and Mo), (W, Cu, Ta, and Ti), (Mg, Cr, Mo, and Ti), (Cr, Mg, Mo, and Ti), (W, Fe, Ta, and Mo), (W, Fe, Mo, and Ti), (W, Mo, Fe, and Ti), (Mg—Al—O, W, Cr, and Mo), (Mg—Al—O, Pt, Cu, and Ti), (W, Mg, Mo, and Ta—N), and (Pt, Hf, Ti, and Ta—N).

For example, when the spin orbit torque wiring 60 has a five-layer structure, it is preferable that a combination of elements respectively included in a first layer, a second layer, a third layer, a fourth layer, and a fifth layer conform with being any one of the following. Here, the first layer, the second layer, the third layer, the fourth layer, and the fifth layer are closer to the laminate 10 in this order. The combination of elements respectively included in the first layer, the second layer, the third layer, the fourth layer, and the fifth layer will be expressed as (the first layer, the second layer, the third layer, the fourth layer, and the fifth layer).

Examples of (the first layer, the second layer, the third layer, the fourth layer, and the fifth layer) include (W, Cr, Mo, Cr, and Ti), (W, Mg, Mo, Cr, and Ti), (W, V, Mo, Cr, and Ti), (Ta, Cr, Mo, Cr, and Ti), (Ta, Mg, Mo, Cr, and Ti), (Ta, V, Mo, Cr, and Ti), (Pt, Al, Ti, Cu, and Mo), (Pt, Cu, Ti, Cu, and Mo), (Pt, Ru, Ti, Cu, and Mo), (Pt, Au, Ti, Cu, and Mo), (Pt, Hf, Ti, Cu, and Mo), (W, V, Ta, Cr, and Mo), (W, Mo, Ta, Cr, and Mo), (W, Mg, Ta, Cr, and Mo), (W, Cr, Ta, Mg, and Mo), (W, Al, Ta, Cr, and Mo), (W, Ti, Ta, Cr, and Mo), (W, Cu, Ta, Cr, and Mo), (W, Ru, Ta, Cr, and Mo), (W, Au, Ta, Cr, and Mo), (W, Hf, Ta, Cr, and Mo), (Mg, Cr, Mo, Cr, and Ti), (Mg, V, Mo, Cr, and Ti), (Cr, V, Mo, Cr, and Ti), (Ru, Al, Ti, Cu, and Mo), (Ru, Cu, Ti, Cu, and Mo), (Ru, Au, Ti, Cu, and Mo), (Ru, Hf, Ti, Cu, and Mo), (Hf, Al, Ti, Cu, and Mo), (Hf, Cu, Ti, Cu, and Mo), (Hf, Ru, Ti, Cu, and Mo), (Hf, Au, Ti, Cu, and Mo), (W, Fe, Ta, Co, and Mo), (W, Fe, Mo, Co, and Ti), (W, Fe, Ti, Co, and Mo), (W, Fe, Hf, Co, and Ti), (W, Co, Ta, Fe, and Mo), (W, Co, Mo, Fe, and Ti), (W, Co, Ti, Fe, and Mo), (W, Co, Hf, Fe, and Ti), (W, V, Fe, Cr, and Mo), (W, Mo, Fe, Cr, and Ti), (W, Mg, Fe, Cr, and Mo), (W, Cr, Fe, Mg, and Mo), (W, Al, Co, Ti, and Mo), (W, Ti, Co, Mo, and Ti), (W, Cu, Co, Ti, and Mo), (W, Ru, Co, Ti, and Mo), (W, Au, Co, Ti, and Mo), (W, Hf, Co, Ti, and Mo), (Mg—Al—O, W, Cr, Mo, and Ti), (Mg—Al—O, W, Mg, Mo, and Ti), (Mg—Al—O, W, V, Mo, and Ti), (Mg—Al—O, Pt, Al, Ti, and Mo), (Mg—Al—O, Pt, Cu, Ti, and Mo), (Mg—Al—O, Pt, Ru, Ti, and Mo), (Mg—Al—O, Pt, Au, Ti, and Mo), (Mg—Al—O, Pt, Hf, Ti, and Mo), (W, Mg, Cr, Mo, and Ti—N), (W, Mg, Cr, Mo, and Ta—N), (W, Mg, Cr, Mo, and Cu—O), (W, Mg, Cr, Mo, and Cu—N), (W, Mg, Cr, Mo, and Hf—O), (Pt, Hf, Cu, Ti, and Ti—N), (Pt, Hf, Cu, Ti, and Ta—N), (Pt, Hf, Cu, Ti, and Cu—O), (Pt, Hf, Cu, Ti, and Cu—N), and (Pt, Hf, Cu, Ti, and Hf—O).

It is more preferable that the combination of elements respectively included in the first layer, the second layer, the third layer, the fourth layer, and the fifth layer conform with being any one of the following. Examples of (the first layer, the second layer, the third layer, the fourth layer, and the fifth layer) preferably include (W, Cr, Mo, Cr, and Ti), (W, Mg, Mo, Cr, and Ti), (Pt, Cu, Ti, Cu, and Mo), (W, Mo, Ta, Cr, and Mo), (W, Mg, Ta, Cr, and Mo), (W, Cr, Ta, Mg, and Mo), (W, Cu, Ta, Cr, and Mo), (Mg, Cr, Mo, Cr, and Ti), (W, Fe, Ta, Co, and Mo), (W, Fe, Mo, Co, and Ti), (W, Fe, Ti, Co, and Mo), (W, Mo, Fe, Cr, and Ti), (Mg—Al—O, W, Cr, Mo, and Ti), (Mg—Al—O, Pt, Cu, Ti, and Mo), (W, Mg, Cr, Mo, and Ta—N), and (Pt, Hf, Cu, Ti, and Ta—N).

In the spin orbit torque wiring 60, the combinations of the materials of the layers are asymmetric in the z direction. In the spin orbit torque wiring 60, the sequence of material types in which the materials of the layers of the spin orbit torque wiring 60 are arranged from the first surface 60A toward the second surface 60B differs from the sequence of material types in which the materials of the layers of the spin orbit torque wiring 60 are arranged from the second surface 60B toward the first surface 60A.

The constitution will be described by presenting specific materials. For example, a case where the spin orbit torque wiring 60 is constituted of four layers in which the first layer 60₁ is made of tungsten, the second layer 60₂ is made of copper, the third layer 60₃ is made of tungsten, and a fourth layer 60₄ is made of tantalum will be described as an example. In this case, the sequence of material types in which the materials of the layers of the spin orbit torque wiring 60 are arranged from the first surface 60A toward the second surface 60B has “W, Cu, W, and Ta”, and the sequence of material types in which the materials of the layers of the spin orbit torque wiring 60 are arranged from the second surface 60B toward the first surface 60A has “Ta, W, Cu, and W”. The sequences of material types “W, Cu, W, and Ta” and “Ta, W, Cu, and W” do not match. That is, in this example, in the spin orbit torque wiring 60, the combinations of the materials of the layers are asymmetric in the z direction.

Similarly, for example, a case where the spin orbit torque wiring 60 is constituted of eight layers in which the first layer 60₁ is made of tantalum, the second layer 60₂ is made of tungsten, the third layer 60₃ is made of copper, the fourth layer 60₄ is made of molybdenum, a fifth layer 60₅ is made of vanadium, a sixth layer 60₆ is made of copper, a seventh layer 60₇ is made of tungsten, and an eighth layer 60₈ is made of cobalt will be described as an example. In this case, the sequence of material types in which the materials of the layers of the spin orbit torque wiring 60 are arranged from the first surface 60A toward the second surface 60B has “Ta, W, Cu, Mo, V, Cu, W, and Co”, and the sequence of material types in which the materials of the layers of the spin orbit torque wiring 60 are arranged from the second surface 60B toward the first surface 60A has “Co, W, Cu, V, Mo, Cu, W, and Ta”. The sequences of material types “Ta, W, Cu, Mo, V, Cu, W, and Co” and “Co, W, Cu, V, Mo, Cu, W, and Ta” do not match. That is, in this example as well, in the spin orbit torque wiring 60, the combinations of the materials of the layers are asymmetric in the z direction.

In contrast, for example, a case where the spin orbit torque wiring 60 is constituted of five layers in which the first layer 60₁ is made of tungsten, the second layer 60₂ is made of copper, the third layer 60₃ is made of tungsten, the fourth layer 60₄ is made of copper, and the fifth layer 60₅ is made of tungsten will be described as an example. In this case, the sequence of material types in which the materials of the layers of the spin orbit torque wiring 60 are arranged from the first surface 60A toward the second surface 60B has “W, Cu, W, Cu, and W”, and the sequence of material types in which the materials of the layers of the spin orbit torque wiring 60 are arranged from the second surface 60B toward the first surface 60A has “W, Cu, W, Cu, and W”. The sequences of material types “W, Cu, W, Cu, and W” and “W, Cu, W, Cu, and W” match. That is, in this example, in the spin orbit torque wiring 60, the combinations of the materials of the layers are symmetric in the z direction.

If the combinations of the materials of the layers in the spin orbit torque wiring 60 are asymmetric in the z direction, the spins generated due to the Rashba effect in the interface between the layers can be efficiently injected into the first ferromagnetic layer 1. This is because canceling out between spins generated due to the Rashba effect in the interfaces can be curbed.

For example, based on an example of the case where the spin orbit torque wiring 60 is constituted of five layers in which the first layer 60₁ is made of tungsten, the second layer 60₂ is made of copper, the third layer 60₃ is made of tungsten, the fourth layer 60₄ is made of copper, and the fifth layer 60₅ is made of tungsten, an example in which spins generated due to the Rashba effect in the interfaces cancel each other out will be described.

In the interface I₁ between the first layer 60₁ and the second layer 60₂, the Rashba effect occurs due to interfaces of dissimilar materials such as tungsten and copper. Similarly, in the interface I₂ between the second layer 60₂ and the third layer 60₃, the Rashba effect occurs due to interfaces of dissimilar materials such as copper and tungsten. If two layers are arranged from the first surface 60A toward the second surface 60B with the interface I₁ interposed therebetween, there are “W and Cu”, and if two layers are arranged from the first surface 60A toward the second surface 60B with the interface I₂ interposed therebetween, there are “Cu and W”. That is, the interface I₁ and the interface I₂ are constituted of a pair made of the same material, and simply the order is reversed. In this case, spins generated in the interface I₁ due to the Rashba effect and spins generated in the interface I₂ due to the Rashba effect are opposite to each other in sign of direction and have the same magnitude. Namely, spins generated in the interface I₁ and spins generated in the interface I₂ cancel each other out.

Similarly, spins generated in the interface I₃ between the third layer 60₃ and the fourth layer 60₄ due to the Rashba effect and spins generated in an interface I₄ between the fourth layer 60₄ and the fifth layer 60₅ due to the Rashba effect also cancel each other out.

In contrast, if the combinations of the materials of the layers in the spin orbit torque wiring 60 are asymmetric in the z direction, all spins generated due to the Rashba effect in the interfaces do not cancel each other out.

In addition, it is preferable that the degree of asymmetry in the spin orbit torque wiring 60 be 0.2 or higher. The degree of asymmetry is obtained by dividing the number of asymmetric interfaces in the spin orbit torque wiring 60 by the total number of interfaces in the spin orbit torque wiring 60. The asymmetric interfaces are interfaces which remain after subtracting paired interfaces from the interfaces in the spin orbit torque wiring 60.

The sequence of material types in which the material types of adjacent layers are arranged from the first surface 60A toward the second surface 60B with one of the paired interfaces interposed therebetween matches the sequence of material types in which the material types of adjacent layers are arranged from the second surface 60B toward the first surface 60A with the other of the paired interfaces interposed therebetween.

For example, the degree of asymmetry will be obtained based on an example of the case where the spin orbit torque wiring 60 is constituted of five layers in which the first layer 60₁ is made of tungsten, the second layer 60₂ is made of copper, the third layer 60₃ is made of tungsten, the fourth layer 60₄ is made of copper, and the fifth layer 60₅ is made of tantalum.

In this example, the total number of interfaces in the spin orbit torque wiring 60 is four. The sequence of material types in which the material types of two layers are arranged with the first interface I₁ interposed therebetween from the first surface 60A toward the second surface 60B has “W and Cu” and the sequence of material types in which the material types of two layers are arranged with the second interface I₂ interposed therebetween from the second surface 60B toward the first surface 60A has “W and Cu”, and therefore they match. For this reason, in this example, the first interface I₁ and the second interface I₂ are paired interfaces.

In addition, the sequence of material types in which the material types of two layers are arranged with the third interface I₃ interposed therebetween from the first surface 60A toward the second surface 60B has “W and Cu”. The third interface I₃ can also be paired up with the second interface I₂. However, since the second interface I₂ is paired up with the first interface I₁ and cannot be paired up twice. For this reason, in this example, the third interface I₃ corresponds to an asymmetric interface.

In addition, the sequence of material types in which the material types of two layers are arranged with the fourth interface I₄ interposed therebetween from the first surface 60A toward the second surface 60B has “Cu and Ta”. The fourth interface I₄ cannot be paired up with any interface. For this reason, in this example, the fourth interface I₄ corresponds to an asymmetric interface.

In this example, there are two asymmetric interfaces. Therefore, the degree of asymmetry in this example becomes “Number of asymmetric interfaces”/“Total number of interfaces”=2/4=0.5.

Similarly, for example, the degree of asymmetry will be obtained based on an example of the case where the spin orbit torque wiring 60 is constituted of seven layers in which the first layer 60₁ is made of tantalum, the second layer 60₂ is made of tungsten, the third layer 60₃ is made of copper, the fourth layer 60₄ is made of molybdenum, the fifth layer 60₅ is made of tungsten, the sixth layer 60₆ is made of tantalum, and the seventh layer 60₇ is made of vanadium.

In this example, the total number of interfaces in the spin orbit torque wiring 60 is six. The sequence of material types in which the material types of two layers are arranged with the first interface I₁ interposed therebetween from the first surface 60A toward the second surface 60B has “Ta and W” and the sequence of material types in which the material types of two layers are arranged with a fifth interface I₅ interposed therebetween from the second surface 60B toward the first surface 60A has “Ta and W”, and therefore they match. For this reason, in this example, the first interface I₁ and the fifth interface I₅ are paired interfaces. In this manner, the paired interfaces may not be adjacent to each other. When the paired interfaces are not adjacent to each other, there is an asymmetric interface between two interfaces constituting paired interfaces in the Z direction.

The sequence of material types in which the material types of two layers are arranged with the second interface I₂ interposed therebetween from the first surface 60A toward the second surface 60B has “W and Cu”. The sequence of material types in which the material types of two layers are arranged with the third interface I₃ interposed therebetween from the first surface 60A toward the second surface 60B has “Cu and Mo”. The sequence of material types in which the material types of two layers are arranged with the fourth interface I₄ interposed therebetween from the first surface 60A toward the second surface 60B has “Mo and W”. The sequence of material types in which the material types of two layers are arranged with a sixth interface I₆ interposed therebetween from the first surface 60A toward the second surface 60B has “Ta and V”. These interfaces cannot be paired up with any interface. For this reason, in this example, each of the second interface I₂, the third interface I₃, the fourth interface I₄, and the sixth interface I₆ corresponds to an asymmetric interface.

In this example, there are four asymmetric interfaces. Therefore, the degree of asymmetry in this example becomes “Number of asymmetric interfaces”/“Total number of interfaces”=4/6=0.667.

Spins generated due to the Rashba effect in the asymmetric interfaces do not completely cancel out spins generated in other interfaces. If the degree of asymmetry in the spin orbit torque wiring 60 is 0.2 or higher, canceling out between spins generated due to the interfacial Rashba effect in the interfaces can be further curbed.

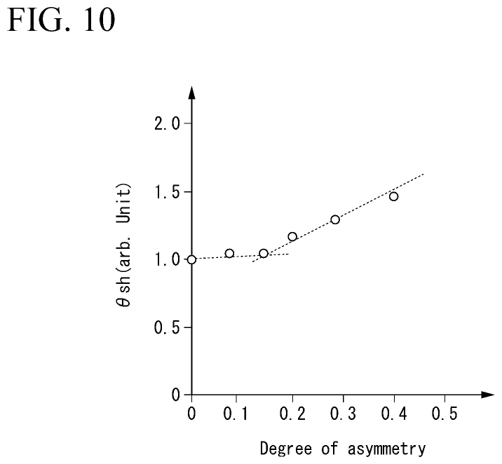

FIG. 10 is a view showing a relationship between a degree of asymmetry of the spin orbit torque wiring and a spin Hall angle of the spin orbit torque wiring. The spin Hall angle is one of indicators for strength of the spin Hall effect and indicates conversion efficiency of a spin current generated with respect to an electric current flowing along the wiring. The larger the spin Hall angle, the higher the conversion efficiency of a spin current. As shown in FIG. 10, if the degree of asymmetry exceeds 0.2, the increasing degree of the spin Hall angle becomes stronger.

In addition, paired interfaces of a plurality of interfaces have different areas. For example, when the first interface I₁ and the second interface I₂ are paired interfaces, the interface I₁ and the interface I₂ have different areas. For example, one of the paired interfaces (for example, the interface I₁) may have a longer length in the x direction than the other of the paired interfaces (for example, the interface I₂). In addition, for example, one of the paired interfaces (for example, the interface I₁) may have a longer width in the y direction than the other of the paired interfaces (for example, the interface I₂). In addition, for example, one of the paired interfaces (for example, the interface I₁) may have a longer length in the x direction and a longer width in the y direction than the other of the paired interfaces (for example, the interface I₂). If the paired interfaces have different areas, it is possible to curb a situation in which spin currents generated due to the interfacial Rashba effect in the interfaces cancel each other out.

In addition, each of a plurality of interfaces may have a different area. For example, each of the first interface I₁, the second interface I₂, the third interface I₃, so on to the n−2th interface Iₙ₋₂, and the n−1th interface Iₙ₋₁ may have a different area. When each of the interfaces has a different area, it is possible to further curb a situation in which spin currents generated due to the interfacial Rashba effect in the interfaces cancel each other out.

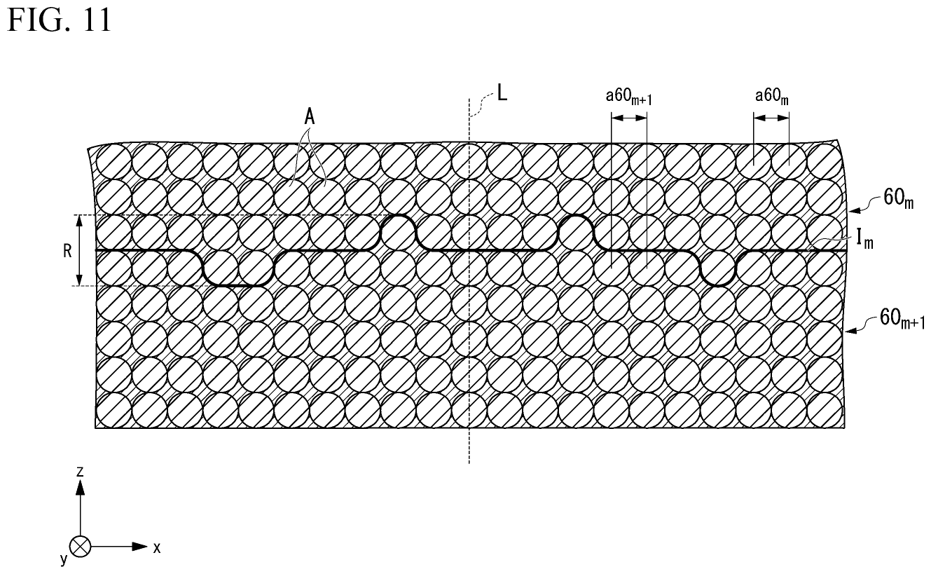

FIG. 11 is an enlarged view of a characteristic portion of the spin orbit torque wiring 60 according to the second embodiment. FIG. 11 schematically shows an arrangement of the atoms A in an mth layer 60ₘ, and an m+1th layer 60ₘ₊1.

For example, it is preferable that at least one interface of the interfaces included in the spin orbit torque wiring 60 have 90% or more of a portion in which the interface roughness is two atomic layers or smaller. In addition, it is preferable that all the interfaces included in the spin orbit torque wiring 60 have 90% or more of a portion in which the interface roughness is two atomic layers or smaller.

The definition of an interface roughness R is similar to that in the first embodiment. First, an interface Iₘ at a position overlapping the first ferromagnetic layer 1 when viewed in the z direction is evaluated along a width of 10 nm in the x direction. For example, when the width of the first ferromagnetic layer 1 in the x direction is 50 nm, the interface Iₘ, is divided into five parts each having a width of 10 nm, and they are individually measured. For example, when the width of the first ferromagnetic layer 1 in the x direction is 45 nm, the interface Iₘ is divided into four parts each having a width of 10 nm at equal intervals, and they are individually measured.

The interface roughness R is obtained as a displacement amount of the atoms A in the interface Iₘ. A portion in which the interface roughness in the interface is two atomic layers or smaller is a portion in which deviation of atoms is within a range of two atoms. For example, as described above, when five parts each having a width of 10 nm are measured, the average value of results of the five parts is obtained. If a portion in which the interface roughness R is two atomic layers or smaller is 90% or more, it can be said that the interface Iₘ, is basically flat excluding local spikes, defect, or the like. If the interface Iₘ, is flat, the Rashba effect can be caused more effectively.

In addition, it is preferable that two layers with at least one interface of the interfaces included in the spin orbit torque wiring 60 interposed therebetween be epitaxially grown. In addition, it is preferable that all two layers with the interface included in the spin orbit torque wiring 60 interposed therebetween be epitaxially grown.

For example, whether or not the mth layer 60ₘ and the m+1th layer 60ₘ+1 are epitaxially grown can be confirmed by the fact that the atoms A are consecutively arrayed in an image of a transmission electron microscope (TEM). When the mth layer 60ₘ and the m+1th layer 60ₘ₊1 are epitaxially grown, as shown in FIG. 11, if an array of the atoms A is confirmed in order from the lower layer, it is possible to draw the line L in which the atoms A are arranged in a row. When these layers are not epitaxially grown, obvious distortion can be confirmed and the line L is disconnected in the middle of the way.

In addition, it is preferable that the lattice misfit rate in two layers with at least one interface of the interfaces included in the spin orbit torque wiring 60 interposed therebetween be lower than 5%. In addition, it is preferable that the lattice misfit rate in all two layers with the interface included in the spin orbit torque wiring 60 interposed therebetween be lower than 5%.

The lattice misfit rate in the interface Iₘ, is obtained by (“Lattice constant a60ₘ, of mth layer 60ₘ,”—“Lattice constant a60ₘ₊₁ of m+1th layer 60ₘ₊₁”)/“Lattice constant a60ₘ, of mth layer 60ₘ,”. If the lattice misfit rate is within the foregoing range, crystallinity of each layer increases so that the flat interface Iₘ, is obtained.

In addition, for example, the interface roughness of the interface may become higher as it is closer to the laminate 10. If an interface far from the first ferromagnetic layer 1 is flat, even spins generated in the interface at a position away from the first ferromagnetic layer 1 can be injected into the first ferromagnetic layer 1.

The magnetoresistive effect element 110 can be manufactured by a procedure similar to that of the magnetoresistive effect element 100. When the interface roughness R of the interface between the layers is set within a predetermined range, every time each of the layers constituting the spin orbit torque wiring 60 is laminated, the surface thereof is subjected to chemical mechanical polishing or plasma treatment.

In the magnetoresistive effect element 110 according to the second embodiment, the combinations of the materials of the layers in the spin orbit torque wiring 60 are asymmetric in the z direction, and therefore it is possible to curb a situation in which spins generated due to the Rashba effect in the interfaces cancel each other out. For this reason, spins can be effectively injected into the first ferromagnetic layer 1 from the spin orbit torque wiring 60, and a reversal current density can be reduced. In addition, since the paired interfaces have different areas, it is possible to further curb a situation in which spins generated in the respective interfaces cancel each other out.

In FIG. 9, an example in which a plurality of interfaces included in the spin orbit torque wiring 60 differ from each other has been described, but there is no need for all the interfaces to have different areas. For example, only two interfaces (the first interface and the second interface) of a plurality of interfaces included in the spin orbit torque wiring 60 may have different areas. In addition, it is preferable that interfaces having different areas in a plurality of interfaces be two interfaces constituting paired interfaces.

### First Modification Example

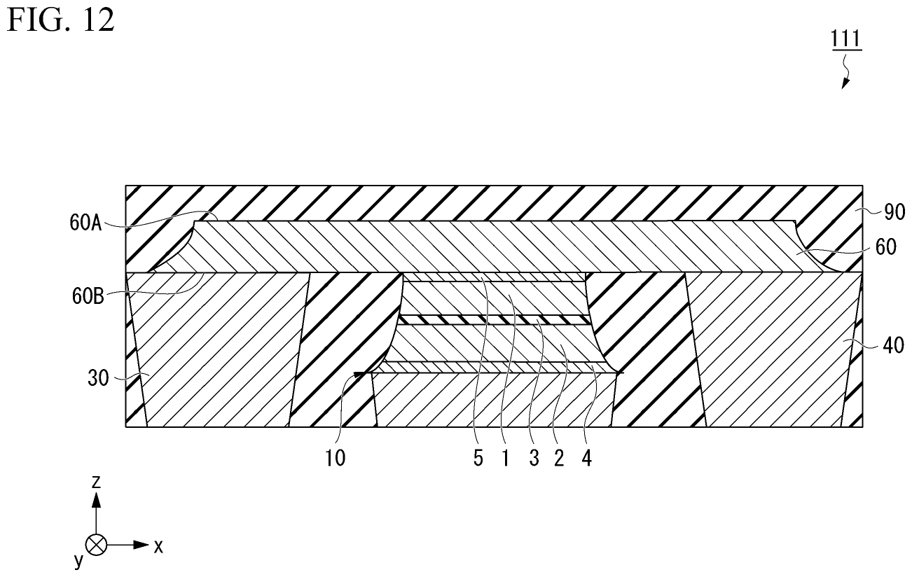

FIG. 12 is a cross-sectional view of a magnetoresistive effect element 111 according to a first modification example of the second embodiment. In the magnetoresistive effect element 111, the same reference signs are applied to constituents similar those of the magnetoresistive effect element 110, and description thereof will be omitted.

The magnetoresistive effect element 111 differs from the magnetoresistive effect element 110 in laminating order of the laminate 10 and the spin orbit torque wiring 60. The spin orbit torque wiring 60 is laminated on the laminate 10.

The laminate 10 has the base layer 4, the second ferromagnetic layer 2, the non-magnetic layer 3, the first ferromagnetic layer 1, and the cap layer 5 in this order from the side closer to the substrate Sub. In the magnetoresistive effect element 111, the second ferromagnetic layer 2 (magnetization fixed layer) is closer to the substrate Sub than the first ferromagnetic layer 1 and is referred to as a bottom pin structure. The length of the first surface of the first ferromagnetic layer 1 on the spin orbit torque wiring 60 side in the x direction is shorter than the length of the second surface on a side opposite to the first surface in the x direction.

The spin orbit torque wiring 60 shown in FIG. 12 has four or more layers. For example, the spin orbit torque wiring 60 shown in FIG. 12 has the first layer 60₁, the second layer 60₂, and so on to n layers (n is an integer of 4 or larger), such as the nth layer 60ₙ, in this order from the side closer to the first surface 60A. In addition, the spin orbit torque wiring 60 shown in FIG. 12 has the first interface I₁, the second interface I₂, and so on to the n−1th interface Iₙ₋₁ in this order from the side closer to the first surface 60A.

In the spin orbit torque wiring 60, the combinations of the materials of the layers are asymmetric in the z direction. In the spin orbit torque wiring 60, the sequence of material types in which the materials of the layers of the spin orbit torque wiring 60 are arranged from the first surface 60A toward the second surface 60B differs from the sequence of material types in which the materials of the layers of the spin orbit torque wiring 60 are arranged from the second surface 60B toward the first surface 60A. For example, the length of the first surface 60A of the spin orbit torque wiring 60 in the x direction is longer than the length of the second surface 60B of the spin orbit torque wiring 60 in the x direction. The paired interfaces in the spin orbit torque wiring 60 have different areas. The interfaces of the spin orbit torque wiring 60 may have different areas.

In addition, for example, the interface roughness of the interface may become lower as it is closer to the laminate 10. If an interface close to the first ferromagnetic layer 1 is flat, more spins can be injected into the first ferromagnetic layer 1 from the interface.

In addition, in FIG. 12, the first via wiring 30 and the second via wiring 40 are connected to the same surface as the surface of the spin orbit torque wiring 60 to which the laminate 10 is connected, but they may be connected to a different surface.

The magnetoresistive effect element 111 according to the first modification example of the second embodiment exhibits effects similar to those of the magnetoresistive effect element 110.

### Second Modification Example

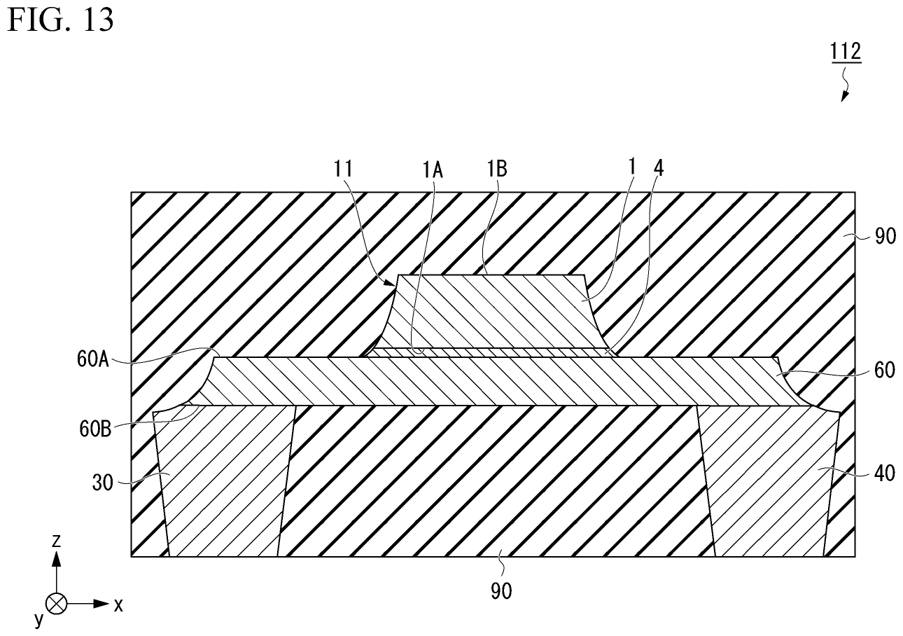

FIG. 13 is a cross-sectional view of a magnetization rotation element 112 according to a second modification example of the second embodiment. The magnetization rotation element 112 differs from the magnetoresistive effect element 110 in that the second ferromagnetic layer 2 and the non-magnetic layer 3 are not provided. The magnetization rotation element 112 is an example of a magnetic element.

The magnetization rotation element 112 is similar to the magnetization rotation element 102 except that the spin orbit torque wiring 60 have four or more layers.

In the magnetization rotation element 112 according to the second modification example, the non-magnetic layer 3 and the second ferromagnetic layer 2 are simply removed from the magnetoresistive effect element 110, and it is possible to achieve effects similar to those of the magnetoresistive effect element 110.

Thus far, preferred aspects of the present invention have been described as examples by describing several embodiments as examples, but the present invention is not limited to these embodiments. For example, characteristic constitutions in each of the embodiments may also be applied to other embodiments and modification examples.

### EXPLANATION OF REFERENCES

1 First ferromagnetic layer
1A First surface
1B Second surface
2 Second ferromagnetic layer
3 Non-magnetic layer
4 Base layer
5 Cap layer
6 Mask layer
10 Laminate
20, 60 Spin orbit torque wiring
21 First layer
22 Second layer
23 Third layer
30 First via wiring
40 Second via wiring
60A First surface
60B Second surface
90 Insulating layer
100, 101, 110, 111 Magnetoresistive effect element
102, 112 Magnetization rotation element
200 Magnetic memory

What is claimed is:

1. A magnetic element comprising:
a spin orbit torque wiring; and
a laminate coming into contact with the spin orbit torque wiring and including a first ferromagnetic layer,
wherein the spin orbit torque wiring includes three or more layers,
combinations of materials of the layers in the spin orbit torque wiring are asymmetric in a lamination direction, and
a sequence of material types in which the materials of the layers of the spin orbit torque wiring are arranged from a first surface in contact with the laminate toward a second surface on a side opposite to the first surface differs from a sequence of material types in which the materials of the layers of the spin orbit torque wiring are arranged from the second surface toward the first surface.

2. The magnetic element according to claim 1,
wherein a degree of asymmetry of the spin orbit torque wiring is 0.2 or higher,
the degree of asymmetry is obtained by dividing the number of asymmetric interfaces in the spin orbit torque wiring by the total number of interfaces in the spin orbit torque wiring,
the asymmetric interfaces are interfaces which remain after subtracting paired interfaces from the interfaces, and
a sequence of material types in which material types of adjacent layers with one of the paired interfaces interposed therebetween are arranged from the first surface toward the second surface matches a sequence of material types in which material types of adjacent layers with the other of the paired interfaces interposed therebetween are arranged from the second surface toward the first surface.

3. The magnetic element according to claim 1,
wherein a layer in contact with the laminate in the spin orbit torque wiring is a non-magnetic layer.

4. The magnetic element according to claim 1,
wherein at least one interface of the interfaces included in the spin orbit torque wiring has 90% or more of a portion in which an interface roughness is two atomic layers or smaller, and
the interface roughness is obtained as a displacement amount of atoms in an interface at a position overlapping the first ferromagnetic layer when viewed in the lamination direction by measuring the interface using a transmission electron microscope.

5. The magnetic element according to claim 1,
wherein a lattice misfit rate between two layers with at least one interface of the interfaces included in the spin orbit torque wiring interposed therebetween is lower than 5%.

6. The magnetic element according to claim 1,
wherein two layers with at least one interface of the interfaces included in the spin orbit torque wiring interposed therebetween are epitaxially grown.

7. The magnetic element according to claim 1,
wherein at least one of the layers included in the spin orbit torque wiring has an impurity concentration of 3 atm % or lower.

8. The magnetic element according to claim 1,
wherein the spin orbit torque wiring has a three-layer structure constituted of a first layer, a second layer, and a third layer in this order from the side closer to the laminate, and
when a combination of elements respectively included in the first layer, the second layer, and the third layer is expressed as (that of the first layer, the second layer, and the third layer), the combination of elements respectively included in the first layer, the second layer, and the third layer conforms with being any one of (W, Cr, and Mo), (W, Mg, and Mo), (Pt, Cu, and Ti), (W, Mo, and Ta), (W, Mg, and Ta), (W, Cr, and Ta), (W, Cu, and Ta), (Mg, Cr, and Mo), (Cr, Mg, and Mo), (W, Fe, and Ta), (W, Fe, and Mo), (W, Mo, and Fe), (Mg—Al—O, W, and Mo), (Mg—Al—O, Pt, and Ti), (W, Mo, and Ta—N), and (Pt, Ti, and Ta—N).

9. The magnetic element according to claim 1,
wherein the spin orbit torque wiring has a four-layer structure constituted of a first layer, a second layer, a third layer, and a fourth layer in this order from the side closer to the laminate, and
when a combination of elements respectively included in the first layer, the second layer, the third layer, and the fourth layer is expressed as (that of the first layer, the second layer, the third layer, and the fourth layer), the combination of elements respectively included in the first layer, the second layer, the third layer, and the fourth layer conforms with being any one of (W, Cr, Mo, and Ti), (W, Mg, Mo, and Ti), (W, Mg, Cr, and Mo), (Pt, Cu, Ti, and Mo), (W, Mo, Ta, and Ti), (W, Mg, Ta, and Mo), (W, Cr, Ta, and Mo), (W, Cu, Ta, and Ti), (Mg, Cr, Mo, and Ti), (Cr, Mg, Mo, and Ti), (W, Fe, Ta, and Mo), (W, Fe, Mo, and Ti), (W, Mo, Fe, and Ti), (Mg—Al—O, W, Cr, and Mo), (Mg—Al—O, Pt, Cu, and Ti), (W, Mg, Mo, and Ta—N), and (Pt, Hf, Ti, and Ta—N).

10. The magnetic element according to claim 1,
wherein the spin orbit torque wiring has a five-layer structure constituted of a first layer, a second layer, a third layer, a fourth layer, and a fifth layer in this order from the side closer to the laminate, and
when a combination of elements respectively included in the first layer, the second layer, the third layer, the fourth layer, and the fifth layer is expressed as (that of the first layer, the second layer, the third layer, the fourth layer, and the fifth layer), the combination of elements respectively included in the first layer, the second layer, the third layer, the fourth layer, and the fifth layer conforms with being any one of (W, Cr, Mo, Cr, and Ti), (W, Mg, Mo, Cr, and Ti), (Pt, Cu, Ti, Cu, and Mo), (W, Mo, Ta, Cr, and Mo), (W, Mg, Ta, Cr, and Mo), (W, Cr, Ta, Mg, and Mo), (W, Cu, Ta, Cr, and Mo), (Mg, Cr, Mo, Cr, and Ti), (W, Fe, Ta, Co, and Mo), (W, Fe, Mo, Co, and Ti), (W, Fe, Ti, Co, and Mo), (W, Mo, Fe, Cr, and Ti), (Mg—Al—O, W, Cr, Mo, and Ti), (Mg—Al—O, Pt, Cu, Ti, and Mo), (W, Mg, Cr, Mo, and Ta—N), and (Pt, Hf, Cu, Ti, and Ta—N).

11. The magnetic element according to claim 1,
wherein the spin orbit torque wiring has a plurality of interfaces between a plurality of layers constituting the spin orbit torque wiring, and
a first interface which is one of the plurality of interfaces differs in area from a second interface different from the first interface of the plurality of interfaces.

12. The magnetic element according to claim 1,
wherein the spin orbit torque wiring has a plurality of interfaces between a plurality of layers constituting the spin orbit torque wiring, and
each of the plurality of interfaces has a different area.

13. The magnetic element according to claim 1,
wherein the spin orbit torque wiring has a plurality of interfaces between a plurality of layers constituting the spin orbit torque wiring,
the plurality of interfaces has paired interfaces,
a sequence of material types in which material types of adjacent layers with one of the paired interfaces interposed therebetween are arranged from the first surface toward the second surface matches a sequence of material types in which material types of adjacent layers with the other of the paired interfaces interposed therebetween are arranged from the second surface toward the first surface, and
two interfaces constituting the paired interfaces have different areas.

14. The magnetic element according to claim 1,
wherein the spin orbit torque wiring has a plurality of interfaces between a plurality of layers constituting the spin orbit torque wiring,
the plurality of interfaces has paired interfaces and asymmetric interfaces,
a sequence of material types in which material types of adjacent layers with one of the paired interfaces interposed therebetween are arranged from the first surface toward the second surface matches a sequence of material types in which material types of adjacent layers with the other of the paired interfaces interposed therebetween are arranged from the second surface toward the first surface, and
the asymmetric interfaces are interfaces which remain after subtracting paired interfaces from the interfaces, and
the asymmetric interfaces are located between two interfaces constituting the paired interfaces in the lamination direction.

15. The magnetic element according to claim 1,
wherein the laminate includes the first ferromagnetic layer, a second ferromagnetic layer, and a non-magnetic layer, and
the non-magnetic layer is located between the first ferromagnetic layer and the second ferromagnetic layer.

16. A magnetic memory comprising:
the magnetic element according to claim 15.
